(19) United States
(12) Patent Application Publication
(10) Pub. No.: US 2022/0283499 A1
(43) Pub. Date: Sep. 8, 2022

(54) COMPOSITION FOR FORMING UNDERLAYER FILM, RESIST PATTERN FORMING METHOD, AND MANUFACTURING METHOD OF ELECTRONIC DEVICE

(71) Applicant: FUJIFILM Corporation, Tokyo (JP)

(72) Inventors: Takeshi KAWABATA, Haibara-gun (JP); Kei YAMAMOTO, Haibara-gun (JP); Kazuyoshi MIZUTANI, Haibara-gun (JP)

(73) Assignee: FUJIFILM Corporation, Tokyo (JP)

(21) Appl. No.: 17/748,500

(22) Filed: May 19, 2022

Related U.S. Application Data
(63) Continuation of application No. PCT/JP2020/042191, filed on Nov. 12, 2020.

(30) Foreign Application Priority Data
Nov. 22, 2019 (JP) 2019-211509

(51) Int. Cl. G03F 7/038; G03F 7/004; G03F 7/32; G03F 7/20

(52) U.S. Cl. CPC G03F 7/0385; G03F 7/0048; G03F 7/322; G03F 7/20

(57) ABSTRACT

The present invention provides a composition for forming an underlayer film, with which an underlayer film having excellent surface flatness and solvent resistance can be formed. In addition, the present invention provides a resist pattern forming method and a manufacturing method of an electronic device, which are related to the composition for forming an underlayer film. The composition for forming an underlayer film according to the present invention is a composition for forming an underlayer film, which is used for forming an underlayer film under a resist film, including a monomer or a polymer containing an aromatic ring and a halogen-based organic solvent, in which a content of the halogen-based organic solvent is 0.001 to 50 ppm by mass with respect to a total mass of the composition for forming an underlayer film.

### CROSS-REFERENCE TO RELATED APPLICATIONS

This application is a Continuation of PCT International Application No. PCT/JP2020/042191 filed on Nov. 12, 2020, which claims priority under 35 U.S.C. § 119(a) to Japanese Patent Application No. 2019-211509 filed on Nov. 22, 2019. The above application is hereby expressly incorporated by reference, in its entirety, into the present application.

### BACKGROUND OF THE INVENTION

### 1. Field of the Invention

The present invention relates to a composition for forming an underlayer film, a resist pattern forming method, and a manufacturing method of an electronic device.

### 2. Description of the Related Art

In processes for manufacturing semiconductor devices such as an integrated circuit (IC), microfabrication by lithography using a resist composition has been performed in the related art, and various pattern forming methods have been proposed. For example, there is also known a method in which an underlayer film is formed on a substrate, a resist composition is further applied on the underlayer film to form a resist film, and subsequent steps are carried out.

As a composition used to form the underlayer film, JP2013-156627A discloses a “resist underlayer film material containing a polymer obtained by a condensation of one or more kinds of a compound represented by General Formula (1-1) with one or more kinds of a compound represented by General Formula (2-3) and an equivalent body thereof to form a condensate, and a condensation of the condensate with one or more kinds of a compound represented by General Formula (2-1) or (2-2) and an equivalent body thereof”.

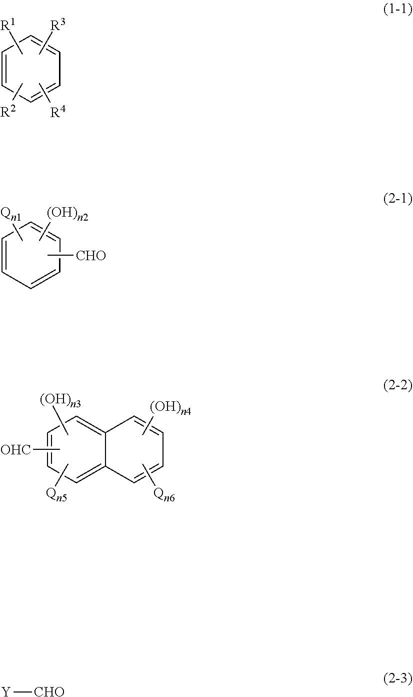

### SUMMARY OF THE INVENTION

In a case of forming the underlayer film on the substrate (especially in a case where the substrate has irregularities), a composition for forming an underlayer film is required to be able to form an underlayer film having a flat surface.

In addition, after forming the underlayer film on the substrate and further forming the resist film, for convenience of handling in the subsequent steps, the resist film on a portion formed on an end part (edge) of the substrate may be removed by using a solvent. In this case, in a case where solvent resistance of the underlayer film is insufficient, the underlayer film may be eroded by the solvent, and the resist film may not be sufficiently supported near the end part of the substrate. Therefore, the composition for forming an underlayer film is also required to be able to form an underlayer film having excellent solvent resistance.

In view of such circumstances, an object of the present invention is to provide a composition for forming an underlayer film, with which an underlayer film having excellent surface flatness and solvent resistance can be formed.

Another object of the present invention is to provide a resist pattern forming method and a manufacturing method of an electronic device, which are related to the composition for forming an underlayer film.

The present inventors have found that the above-described objects can be achieved by the following configurations.

[1]

A composition for forming an underlayer film, which is used for forming an underlayer film under a resist film, the composition comprising:

a monomer or a polymer containing an aromatic ring; and

a halogen-based organic solvent including 1 or more carbon atoms,

in which a content of the halogen-based organic solvent is 0.001 to 50 ppm by mass with respect to a total mass of the composition for forming an underlayer film.

[2]

The composition for forming an underlayer film according to [1],

in which the content of the halogen-based organic solvent is 0.01 to 10 ppm by mass with respect to the total mass of the composition for forming an underlayer film.

[3]

The composition for forming an underlayer film according to [1] or [2], further comprising:

a crosslinking agent.

[4]

The composition for forming an underlayer film according to any one of [1] to [3], further comprising:

an acid generator.

[5]

The composition for forming an underlayer film according to [4],

in which the acid generator is a compound represented by any one of General Formula (1), (2), or (3),

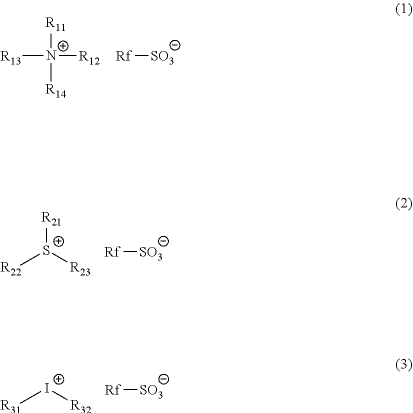

in General Formulae (1) to (3), R₁₁ to R₁₄, R₂₁ to R₂₃, R₃₁, and R₃₂ each independently represent a hydrogen atom, an alkyl group, or an aryl group, and Rf represents an organic group having one or more fluorine atoms,

in General Formula (2), two of R₂₁ to R₂₃ may be bonded to each other to form a ring.

[6]

The composition for forming an underlayer film according to any one of [1] to [5],

in which the halogen-based organic solvent includes one or more kinds selected from the group consisting of methylene chloride, chloroform, trichloroethylene, o-dichlorobenzene, and benzotrifluoride.

[7]

The composition for forming an underlayer film according to any one of [1] to [6],

in which the composition for forming an underlayer film includes the polymer containing an aromatic ring, and

the polymer containing an aromatic ring is a novolac resin having one or more repeating units represented by any of General Formula (A01), . . . , or (A06),

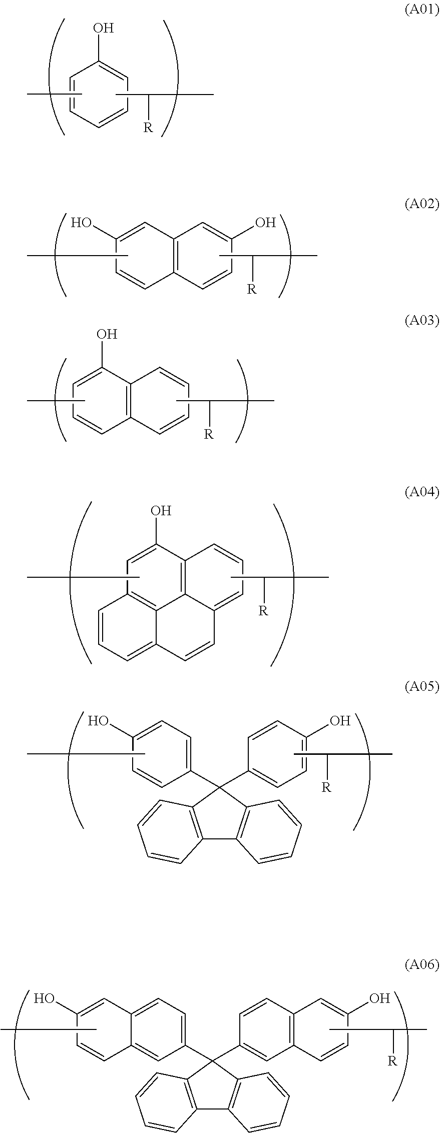

in General Formulae (A01) to (A06), R represents a hydrogen atom, an alkyl group, an alkenyl group, an alicyclic group, or an aryl group.

[8]

The composition for forming an underlayer film according to [7],

in which the content of the halogen-based organic solvent is 0.1 to 10 ppm by mass with respect to a content of the novolac resin.

[9]

A resist pattern forming method comprising:

a step of forming an underlayer film on a substrate by using the composition for forming an underlayer film according to any one of [1] to [8];

a step of forming a second underlayer film on the underlayer film by using a composition for forming a second underlayer film, which includes a silicon atom-containing compound;

a step of forming a resist film on the second underlayer film by using a resist composition;

a step of exposing the resist film; and

a step of developing the exposed resist film with a developer to form a resist pattern.

[10]

The resist pattern forming method according to [9],

in which the exposure is a liquid immersion exposure.

[11]

The resist pattern forming method according to [9] or [10],

in which the developer is a developer including an organic solvent.

[12]

The resist pattern forming method according to [9] or [10],

in which the developer is an alkali developer.

[13]

A manufacturing method of an electronic device, comprising:

the resist pattern forming method according to any one of [9] to [12].

According to the present invention, it is possible to provide a composition for forming an underlayer film, with which an underlayer film having excellent surface flatness and solvent resistance can be formed.

In addition, it is possible to provide a resist pattern forming method and a manufacturing method of an electronic device, which are related to the composition for forming an underlayer film.

### DESCRIPTION OF THE PREFERRED EMBODIMENTS

Hereinafter, an example of forms for carrying out the present invention will be described.

In the present specification, the numerical value range indicated by using “to” means a range including the numerical values before and after “to” as the lower limit value and the upper limit value, respectively.

In citations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

The substituent is intended as a monovalent substituent unless otherwise specified.

An “organic group” in the present specification refers to a group including at least one carbon atom.

In the present specification, examples of the halogen atom include a fluorine atom, a chlorine atom, a bromine atom, and an iodine atom.

“(Meth)acryl” in the present specification is a generic term encompassing acryl and methacryl, and means “at least one of acryl or methacryl”. Similarly, “(meth)acrylic acid” means “at least one of acrylic acid or methacrylic acid”.

“Actinic rays” or “radiation” in the present specification means, for example, a bright line spectrum of a mercury lamp, far ultraviolet rays typified by an excimer laser, extreme ultraviolet rays (EUV light), X-rays, electron beams (EB), or the like. In the present specification, the term “light” means an actinic ray or a radiation.

Unless otherwise specified, “exposure” in the present specification encompasses not only exposure by a bright line spectrum of a mercury lamp, far ultraviolet rays typified by an excimer laser (ArF excimer laser and the like), extreme ultraviolet rays, X-rays, EUV light, or the like, but also drawing by particle beams such as electron beams and ion beams.

1 Å is 1×10⁻¹⁰m.

In the present specification, a weight-average molecular weight (Mw) and a dispersity are values expressed in terms of standard polystyrene, which are obtained by gel permeation chromatography (GPC) under the following conditions.
Column type: TSK gel Multipore HXL-M (manufactured by Tosoh Corporation, 7.8 mmID×30.0 cm)
Developing solvent: tetrahydrofuran (THF)
Column temperature: 40° C.
Flow rate: 1 ml/min
Sample injection amount: 10 μl
Device name: HLC-8120 (manufactured by Tosoh Corporation)

[Composition for Forming Underlayer Film]

A composition for forming an underlayer film according to an embodiment of the present invention is a composition for forming an underlayer film, which is used for forming an underlayer film under a resist film, including a monomer or a polymer containing an aromatic ring and a halogen-based organic solvent including 1 or more carbon atoms (simply referred to as a halogen-based organic solvent), in which a content of the halogen-based organic solvent is 0.001 to 50 ppm by mass with respect to a total mass of the composition for forming an underlayer film.

The mechanism capable of solving the above-described problems by adopting such a configuration of the composition for forming an underlayer film is not always clear, but the present inventors speculate as follows.

That is, since the composition for forming an underlayer film according to the embodiment of the present invention includes a certain amount or more of the halogen-based organic solvent, it is presumed that the above-described monomer or polymer containing an aromatic ring can be satisfactorily dispersed in the composition for forming an underlayer film, and in a case of forming the underlayer film, it is difficult to form irregularities derived from aggregates of the monomer or polymer containing an aromatic ring, and the like.

On the other hand, since the content of the halogen-based organic solvent is a certain amount or less, it is presumed that the halogen-based organic solvent does not easily remain in the underlayer film, and in a case where the underlayer film comes into content with a solvent, dissolution of the underlayer film due to the presence of the halogen-based organic solvent in the underlayer film is less likely to occur, so that the underlayer film has excellent solvent resistance.

Hereinafter, the fact that the underlayer film formed of the composition for forming an underlayer film according to the embodiment of the present invention has excellent solvent resistance and/or surface flatness is also referred to as that the effects of the present invention are excellent.

<Monomer or Polymer Containing Aromatic Ring (Aromatic Ring-Containing Compound)>

The composition for forming an underlayer film according to the embodiment of the present invention includes a monomer or a polymer containing an aromatic ring.

The monomer or the polymer containing an aromatic ring (monomer containing an aromatic ring or polymer containing an aromatic ring) is also collectively referred to as an aromatic ring-containing compound.

The aromatic ring in the aromatic ring-containing compound may be monocyclic or polycyclic, and the aromatic ring may be an aromatic hydrocarbon ring or an aromatic heterocyclic ring. The number of ring-membered atoms in the above-described aromatic ring is preferably 5 to 25 and more preferably 6 to 20.

The number of aromatic rings in one repeating unit in the polymer containing an aromatic ring, which contains the aromatic ring, or in the monomer containing an aromatic ring is 1 or more, and preferably 1 to 10 and more preferably 1 to 4.

Usually, the polymer containing an aromatic ring is a polymer (resin) having a repeating unit derived from the monomer containing an aromatic ring.

That is, as the monomer containing an aromatic ring, a compound containing an aromatic ring, which is a monomer from which (a part or all) of repeating units included in the polymer containing an aromatic ring are derived, can be used.

The composition for forming an underlayer film may include only the monomer containing an aromatic ring, may include only the polymer containing an aromatic ring, or may include both the monomer containing an aromatic ring and the polymer containing an aromatic ring.

The polymer containing an aromatic ring is not particularly limited as long as it has an aromatic ring, and examples thereof include a novolac resin, a (meth)acrylic resin, a styrene-based resin, a cellulose resin, an aromatic polyester resin, an aromatic polyimide resin, a polybenzoxazole-based resin, an aromatic polyamide resin, an acenaphthylene-based resin, and an isocyanuric acid-based resin.

In addition, if possible, the polymer containing an aromatic ring may be a copolymer having a plurality types of repeating units in the above-described resin (a styrene-(meth)acrylic copolymer resin, a styrene-acenaphthylene-based copolymer resin, and the like).

As the above-described aromatic polyamide resin and the above-described aromatic polyimide resin, for example, resin compounds described in JP4120584B, resin compounds described in paragraphs 0021 to 0053 of JP4466877B, and resin compounds described in paragraphs 0025 to 0050 of JP4525940B can be used.

In addition, as the above-described novolac resin, resin compounds described in paragraphs 0015 to 0058 of JP5215825B and paragraphs 0023 to 0041 of JP5257009B can be used.

As the above-described acenaphthylene-based resin, for example, resin compounds described in paragraphs 0032 to 0052 of JP4666166B, resin compounds described in paragraphs 0037 to 0043 of JP4388429B, polymers described in paragraphs 0026 to 0065 of JP5040839B, and resin compounds described in paragraphs 0015 to 0032 of JP4892670B can be used.

The aromatic ring-containing compound preferably contains a crosslinking reactive group capable of crosslinking with a crosslinkable group of a crosslinking agent described later, and also preferably contains a hydroxyl group (preferably an aromatic hydroxyl group and more preferably a phenolic hydroxyl group).

In addition, the monomer containing an aromatic ring also preferably contains a lactone structure which can be contained in a resin (A) described later. In addition, the polymer containing an aromatic ring also preferably contains a repeating unit containing a lactone structure.

A content of the repeating unit containing an aromatic ring (preferably, the repeating unit having an aromatic hydroxyl group) in the polymer containing an aromatic ring is preferably 30% to 100% by mass, more preferably 50% to 100% by mass, and still more preferably 75% to 100% by mass with respect to all repeating units of the polymer containing an aromatic ring.

A weight-average molecular weight of the polymer containing an aromatic ring is preferably 250 to 30000 and more preferably 1000 to 7000.

(Novolac Resin)

The polymer containing an aromatic ring is preferably a novolac resin.

The novolac resin has a hydroxyl group (aromatic hydroxyl group).

The number of hydroxyl groups included in the novolac resin is not limited, and for example, it is preferable that more than half (preferably, 75 to 100 mol % and more preferably 80 to 100 mol %) of all repeating units of the novolac resin have 1 to 8 (preferably 1 or 2) hydroxyl groups (preferably, aromatic hydroxyl groups).

The novolac resin preferably has a repeating unit represented by General Formula (A00).

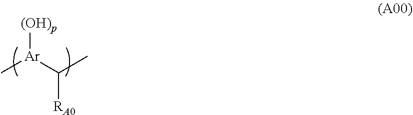

In General Formula (A00), Ar represents a group having an aromatic ring. However, all bonding sites bonded to Ar in General Formula (A00) directly bond to the aromatic ring in Ar. For example, all p pieces of OH in “—(OH)ₚ” are directly bonded to the aromatic ring in Ar.

The aromatic ring in Ar may be monocyclic or polycyclic, and the aromatic ring may be an aromatic hydrocarbon ring or an aromatic heterocyclic ring. The number of ring-membered atoms in the above-described aromatic ring is preferably 5 to 25 and more preferably 6 to 20.

In a case where Ar has a plurality of aromatic rings, the plurality of aromatic rings may be the same or different from each other.

In a case where Ar has a plurality of aromatic rings, it is preferable that the plurality of aromatic rings are bonded by a single bond and/or a bond through one atom (preferably, a carbon atom), respectively.

Examples of Ar include a benzene ring group, a naphthalene ring group, a pyrene ring group, a 9,9-diphenylfluorene ring group, and a 6,6′-(9H-fluorene-9,9′-diyl)bis(naphthalene) ring group.

Ar may or may not have a substituent other than “—(OH)ₚ”.

In General Formula (A00), p represents an integer of 1 or more, and is preferably an integer of 1 to 8 and more preferably an integer of 1 or 2.

In General Formula (A00), R_{A0} represents a hydrogen atom or a substituent.

As the above-described substituent, an alkyl group, an alkenyl group, an alicyclic group, or an aryl group is preferable.

The above-described alkyl group and alkenyl group may be linear or branched. The number of carbon atoms in the above-described alkyl group is preferably 1 to 10. The number of carbon atoms in the above-described alkenyl group is preferably 2 to 10.

The above-described alicyclic group may be monocyclic or polycyclic. The number of carbon atoms in the above-described alicyclic group is preferably 1 to 20 and more preferably 1 to 10. Examples of a polycyclic alicyclic group include groups having a preferred skeleton of a bridged alicyclic hydrocarbon group having 5 to 20 carbon atoms, which will be described later, and among these, a norbornyl group is preferable.

The above-described aryl group may be monocyclic or polycyclic. The number of carbon atoms in the above-described aryl group is preferably 1 to 20 and more preferably 1 to 10.

The novolac resin may have one type of the repeating unit represented by General Formula (A00) alone, or may have two or more types thereof.

Among these, the novolac resin is preferably a novolac resin having one or more repeating units represented by any of General Formula (A01), . . . , or (A06).

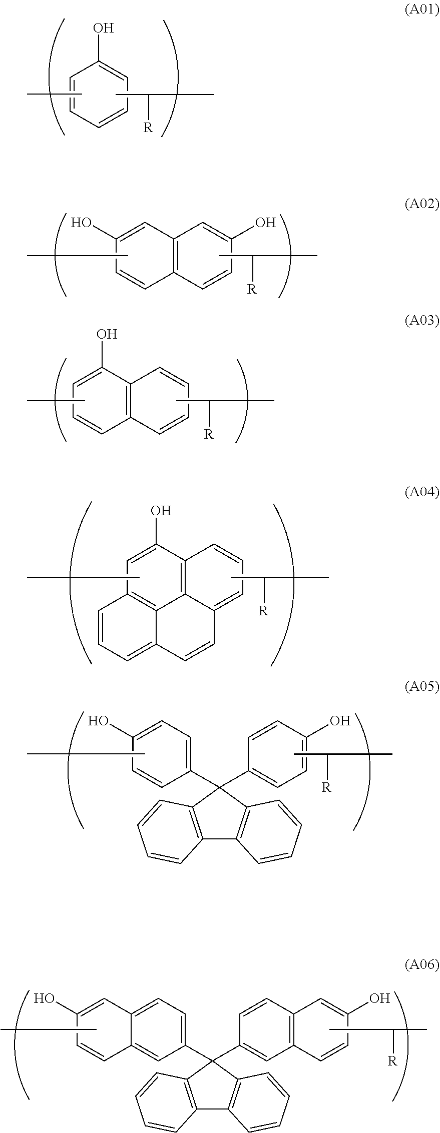

In General Formulae (A01) to (A06), R represents a hydrogen atom, an alkyl group, an alkenyl group, an alicyclic group, or an aryl group.

The above-described alkyl group, alkenyl group, alicyclic group, and aryl group are the same as the alkyl group, alkenyl group, alicyclic group, and aryl group described as R_{A0} in General Formula (A00), respectively.

The novolac resin may have one type of repeating unit represented by General Formulae (A01) to (A06) alone, or may have two or more types thereof.

In all repeating units of the novolac resin, the content of the repeating unit represented by General Formula (A00) (preferably, the repeating unit represented by General Formulae (A01) to (A06)) is preferably 50% to 100% by mass, more preferably 75% to 100% by mass, and still more preferably 95% to 100% by mass with respect to all repeating units of the novolac resin.

(Polymer Obtained by Polymerizing (Copolymerizing) Compound Having One or More Addition-Polymerizable Unsaturated Bonds)

The polymer containing an aromatic ring may be a polymer obtained by polymerizing (copolymerizing) a compound having one or more addition-polymerizable unsaturated bonds. Examples of the above-described compound include compounds having one or more addition-polymerizable unsaturated bonds, selected from acrylic acid esters, acrylamides, methacrylic acid esters, methacrylamides, allyl compounds, vinyl ethers, vinyl esters, styrenes, crotonic acid esters, and acenaphthylenes.

Examples of the acrylic acid esters include alkyl acrylates having an alkyl group having 1 to 10 carbon atoms.

Examples of the methacrylic acid esters include alkyl methacrylates having an alkyl group having 1 to 10 carbon atoms.

Examples of the acrylamides include acrylamide, N-alkylacrylamide, N-arylacrylamide, N,N-dialkylacrylamide, N,N-diarylacrylamide, N-methyl-N-phenylacrylamide, and N-2-acetamide ethyl-N-acetylacrylamide.

Examples of the methacrylamides include methacrylamide, N-alkylmethacrylamide, N-arylmethacrylamide, N,N-dialkylmethacrylamide, N,N-diarylmethacrylamide, N-methyl-N-phenylmethacrylamide, and N-ethyl-N-phenylmethacrylamide.

Examples of the vinyl ethers include alkyl vinyl ethers and vinyl aryl ethers.

Examples of the vinyl esters include vinyl butyrate, vinyl isobutyrate, and vinyl trimethyl acetate.

Examples of the styrenes include styrene, hydroxystyrene, alkylstyrene, alkoxystyrene, and halogen styrene.

Examples of the crotonic acid esters include alkyl crotonic acid such as butyl crotonic acid, hexyl crotonic acid, and glycerin monocrotonate.

Examples of the acenaphthylene include compounds represented by General Formula (AN).

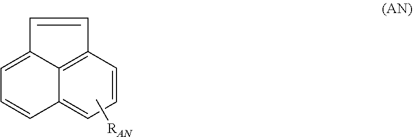

In General Formula (AN), R_{AN} represents a hydrogen atom, a hydroxyl group, an alkyl group having 1 to 10 carbon atoms, a cycloalkyl group having 1 to 10 carbon atoms, an alkoxy group, an acyloxy group, an alkoxycarbonyl group, a carboxyl group, or —OC(═O)R_{AO} (R_{AO} is an alkyl group having 1 to 10 carbon atoms or a cycloalkyl group having 1 to 10 carbon atoms).

The above-described alkyl group (including the alkyl group in R_{AO}), alkoxy group, acyloxy group, and alkoxycarbonyl group may be linear or branched.

Examples of a substituent which can be included in the above-described alkyl group (including the alkyl group in R_{AO}), alkoxy group, acyloxy group, and alkoxycarbonyl group include a fluorine atom.

In addition, examples of the compound having one or more addition-polymerizable unsaturated bonds include itaconic acid dialkyls, maleic acid or fumaric acid dialkyl esters or monoalkyl esters, crotonic acid, itaconic acid, maleic acid anhydride, maleimide, acrylonitrile, methacrylonitrile, and maleylonitrile.

In addition, as the compound having one or more addition-polymerizable unsaturated bonds, it is also preferable to use an addition-polymerizable unsaturated compound which can be copolymerized with a polymer containing at least one hydroxyl group as a crosslinking reactive group per repeating unit.

In a case where the polymer containing an aromatic ring is the polymer obtained by polymerizing (copolymerizing) a compound having one or more addition-polymerizable unsaturated bonds, a polymerization method may be, for example, any of a random polymer, a block polymer, or a graft polymer.

The polymer containing an aromatic ring can be synthesized by a method such as a step-growth polymerization, a radical polymerization, an anionic polymerization, and/or a cationic polymerization. Examples of the form of polymerization include various methods such as a solution polymerization, a suspension polymerization, an emulsion polymerization, and a bulk polymerization.

Examples of the polymer obtained by polymerizing (copolymerizing) a compound having one or more addition-polymerizable unsaturated bonds include hydroxystyrene homopolymers (p-hydroxystyrene homopolymers, m-hydroxystyrene homopolymers, and the like), and copolymers having a hydroxystyrene structure (copolymer having a p-hydroxystyrene structure and a copolymer having an m-hydroxystyrene structure).

In the above-described copolymer (copolymer having a hydroxystyrene structure), examples of a copolymerized portion include a repeating unit represented by General Formula (B1) and a repeating unit represented by General Formula (B2).

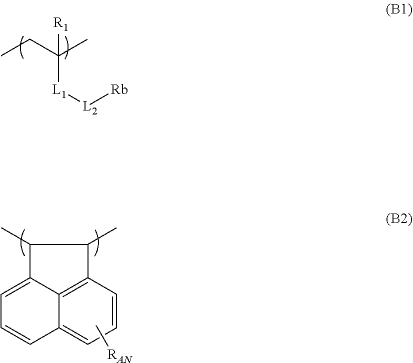

In General Formula (B1), R₁ represents a hydrogen atom, an alkyl group having 1 to 3 carbon atoms, a cyano group, or a halogen atom, and a hydrogen atom or a methyl group is preferable.

L₁ represents a single bond, —COO—, —CON(R₃)—, or an arylene group, in which R₃ represents a hydrogen atom or an alkyl group having 1 to 3 carbon atoms, and a single bond, —COO—, or a phenylene group is preferable.

L₂ represents a single bond, an alkylene group having 1 to 10 carbon atoms, an arylene group having 6 to 18 carbon atoms, —COO—, or —O—, and a single bond, an alkylene group having 1 to 4 carbon atoms, or a phenylene group is preferable.

Rb represents an alkyl group having 1 to 10 carbon atoms, a cycloalkyl group having 4 to 30 carbon atoms, a bridged alicyclic hydrocarbon group having 5 to 25 carbon atoms, or an aryl group having 6 to 18 carbon atoms, and an alkyl group having 1 to 8 carbon atoms (methyl group, ethyl group, butyl group, t-butyl group, and the like), a cycloalkyl group having 5 to 8 carbon atoms (cyclohexyl group, cyclooctyl group, and the like), a bridged alicyclic hydrocarbon group having 5 to 20 carbon atoms, or an aryl group having 6 to 12 carbon atoms (phenyl group, naphthyl group, and the like) is preferable.

Examples of a substituent which may be included in these groups include a halogen atom (Cl, Br, and the like), a cyano group, an alkyl group having 1 to 4 carbon atoms, a hydroxyl group, an alkoxy group having 1 to 4 carbon atoms, an acyl group having 1 to 4 carbon atoms, and an aryl group having 6 to 12 carbon atoms.

Preferred skeletons of the above-described bridged alicyclic hydrocarbon group having 5 to 20 carbon atoms are shown below.

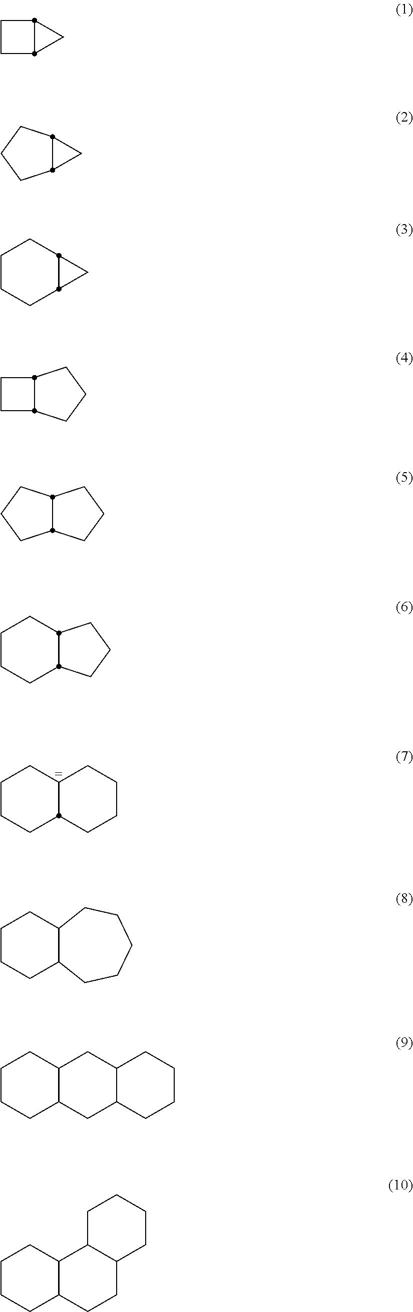

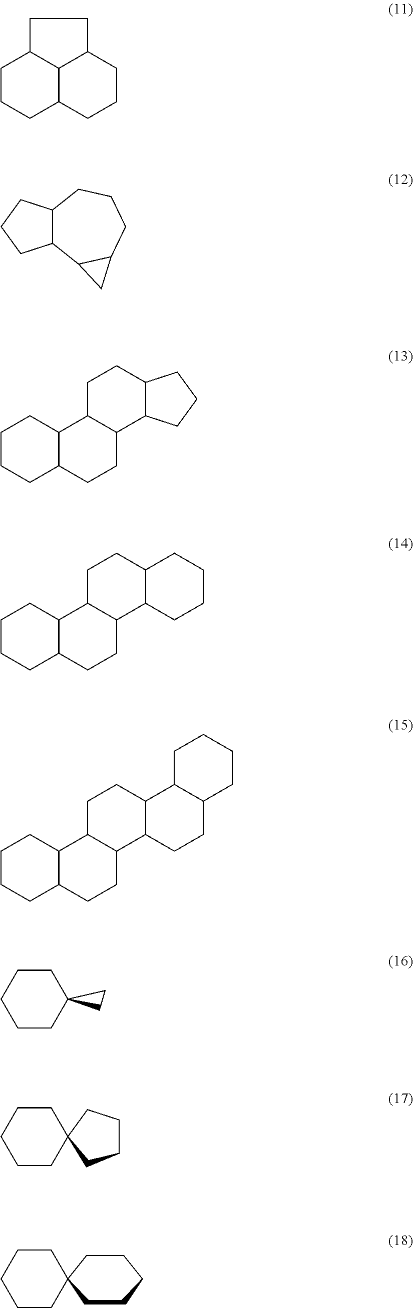

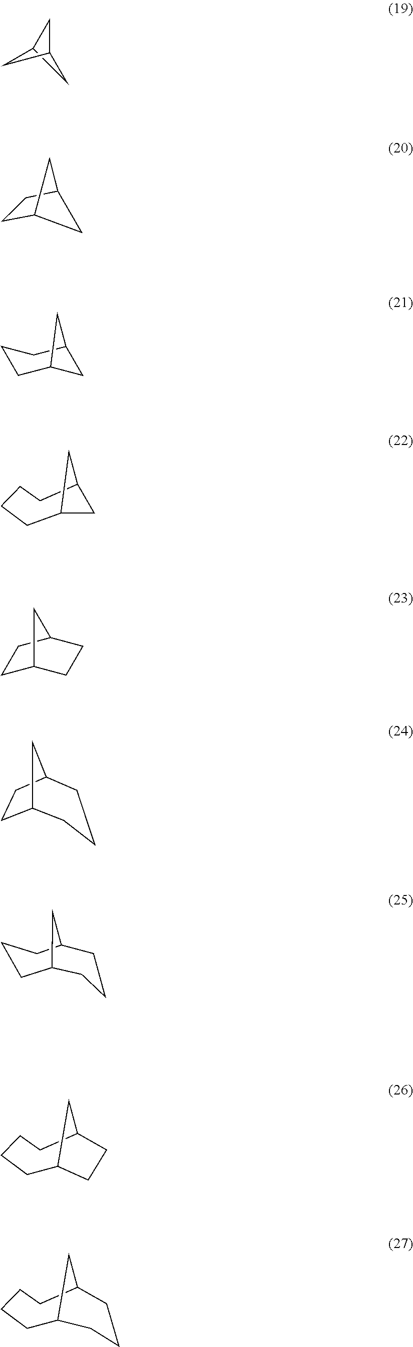

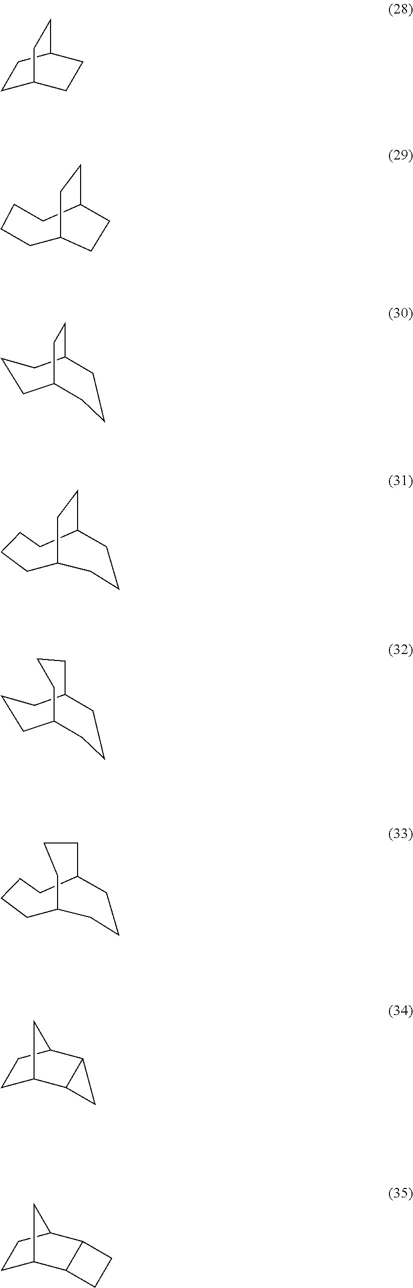

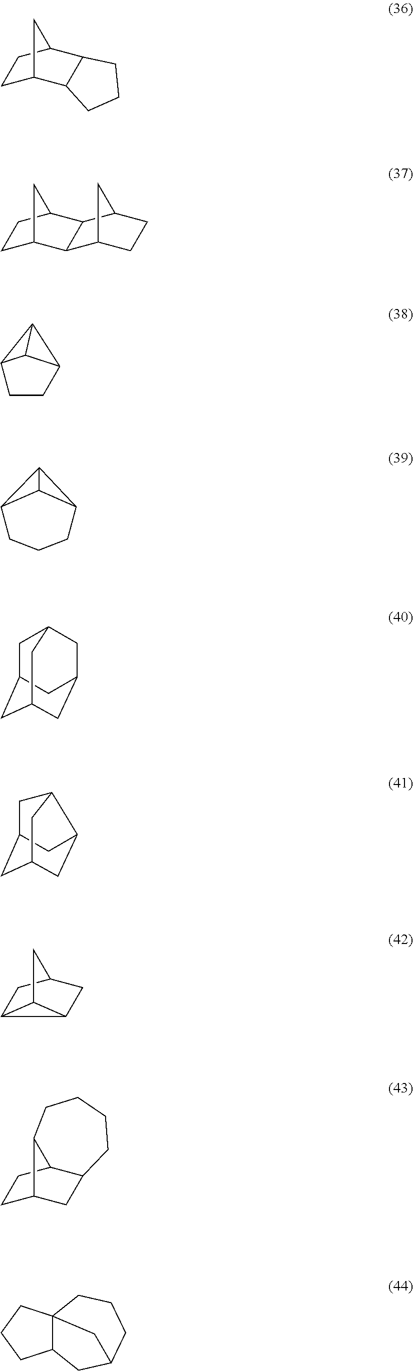

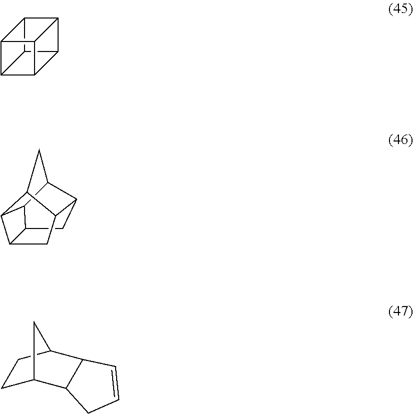 [SMILES: C12C3C4C1C1C2C3C41 ; C1C2C3CC4C5CC3C1C5C24 ; C1=CC2C3CCC(C3)C2C1]

In General Formula (B2), R_{AN} is the same as R_{AN} in General Formula (AN).

In a case where the polymer containing an aromatic ring is the above-described copolymer, the total content of the repeating unit represented by General Formula (B1) and the repeating unit represented by General Formula (B2) is preferably 0.1% to 80% by mass and more preferably 1% to 60% by mass with respect to all repeating units of the above-described copolymer.

In a case where the polymer containing an aromatic ring is the above-described copolymer, the total content of repeating units derived from hydroxystyrene is preferably 20% to 99.9% by mass and more preferably 40% to 95% by mass with respect to all repeating units of the above-described copolymer.

For the purpose of improving film-forming properties, adhesiveness, developability, and the like, the above-described copolymer may by a copolymer containing other repeating units in addition to the repeating unit represented by General Formula (B1) and the repeating unit represented by General Formula (B2). Examples of a monomer corresponding to such other repeating units include a compound having one or more addition-polymerizable unsaturated bonds, selected from acrylic acid esters, methacrylic acid esters, acrylamides, methacrylamides, allyl compounds, vinyl ethers, and vinyl esters.

The compound having one or more addition-polymerizable unsaturated bonds are shown below.

In the following examples, an alkyl group may have a cyclic structure.

Examples of the acrylic acid esters include alkyl acrylates (preferably having 1 to 10 carbon atoms in the alkyl group) (for example, methyl acrylate, ethyl acrylate, propyl acrylate, amyl acrylate, cyclohexyl acrylate, ethylhexyl acrylate, octyl acrylate, t-octyl acrylate, chloroethyl acrylate, trimethylolpropane monoacrylate, pentaerythritol monoacrylate, benzyl acrylate, methoxybenzyl acrylate, furfuryl acrylate, tetrahydrofurfuryl acrylate, and the like).

Examples of the methacrylic acid esters include alkyl methacrylates (preferably having 1 to 10 carbon atoms in the alkyl group) (for example, methyl methacrylate, ethyl methacrylate, propyl methacrylate, isopropyl methacrylate, amyl methacrylate, hexyl methacrylate, cyclohexyl methacrylate, benzyl methacrylate, chlorobenzyl methacrylate, octyl methacrylate, trimethylolpropane monomethacrylate, pentaerythritol monomethacrylate, furfuryl methacrylate, tetrahydrofurfuryl methacrylate, and the like).

Examples of the acrylamides include acrylamide, N-alkylacrylamide (preferably having 1 to 10 carbon atoms in the alkyl group; for example, methyl group, ethyl group, propyl group, butyl group, t-butyl group, heptyl group, octyl group, cyclohexyl group, hydroxyethyl group, and the like), N,N-dialkylacrylamide (preferably having 1 to 10 carbon atoms in the alkyl group; for example, methyl group, ethyl group, butyl group, isobutyl group, ethylhexyl group, cyclohexyl group, and the like), N-hydroxyethyl-N-methylacrylamide, and N-2-acetamide ethyl-N-acetylacrylamide.

Examples of the methacrylamides include methacrylamide, N-alkylmethacrylamide (preferably having 1 to 10 carbon atoms in the alkyl group; for example, methyl group, ethyl group, t-butyl group, ethylhexyl group, hydroxyethyl group, cyclohexyl group, and the like), N,N-dialkylmethacrylamides (as the alkyl group, ethyl group, propyl group, butyl group, and the like), and N-hydroxyethyl-N-methylmethacrylamide.

Examples of the allyl compounds include allyl esters (for example, allyl acetate, allyl caproate, allyl caprylate, allyl laurate, allyl palmitate, allyl stearate, allyl benzoate, allyl acetoacetate, allyl lactate, and the like), and allyloxyethanol.

Examples of the vinyl ethers include alkyl vinyl ethers (for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, and the like).

Examples of the vinyl esters include vinyl butyrate, vinyl isobutyrate, vinyl trimethyl acetate, vinyl diethyl acetate, vinyl barate, vinyl caproate, vinyl chloroacetate, vinyl dichloroacetate, vinyl methoxy acetate, vinyl butoxy acetate, vinyl acetoacetate, vinyl lactate, vinyl-β-phenyl butyrate, and vinyl cyclohexyl carboxylate.

As other compounds having one or more addition-polymerizable unsaturated bonds, for example, itaconic acid dialkyls (for example, dimethyl itaconic acid, diethyl itaconic acid, dibutyl itaconic acid, and the like), fumaric acid dialkyl esters (for example, dibutyl fumarate) or monoalkyl esters, acrylic acid, methacrylic acid, crotonic acid, itaconic acid, maleic acid anhydride, maleimide, acrylonitrile, methacrylonitrile, and maleylonitrile can be mentioned.

The polymer obtained by polymerizing (copolymerizing) a compound having one or more addition-polymerizable unsaturated bonds is shown below.

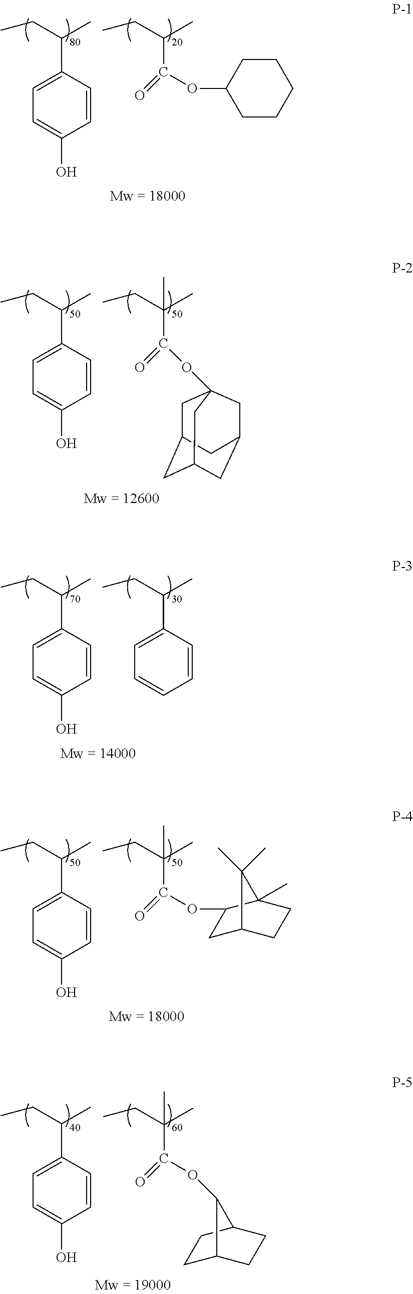

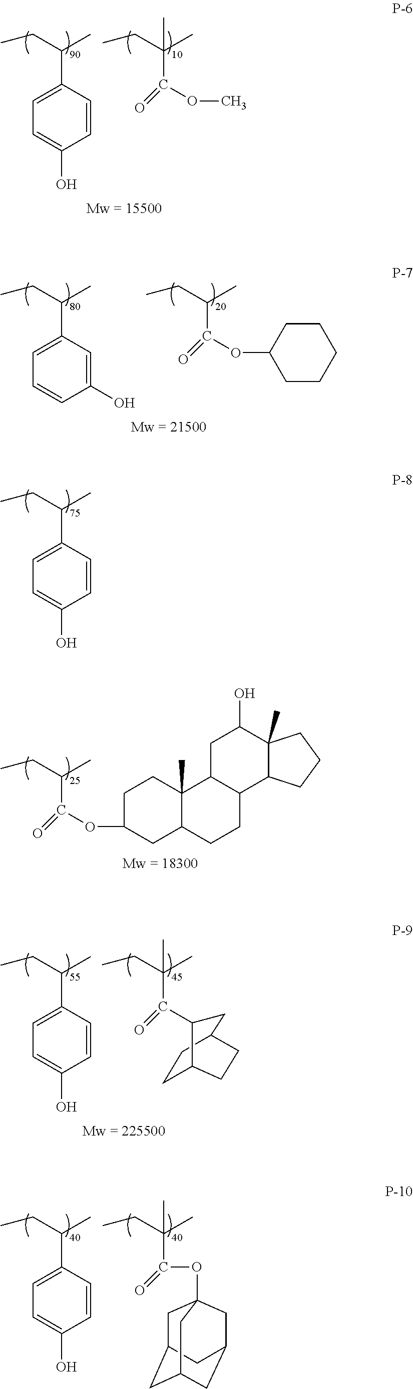

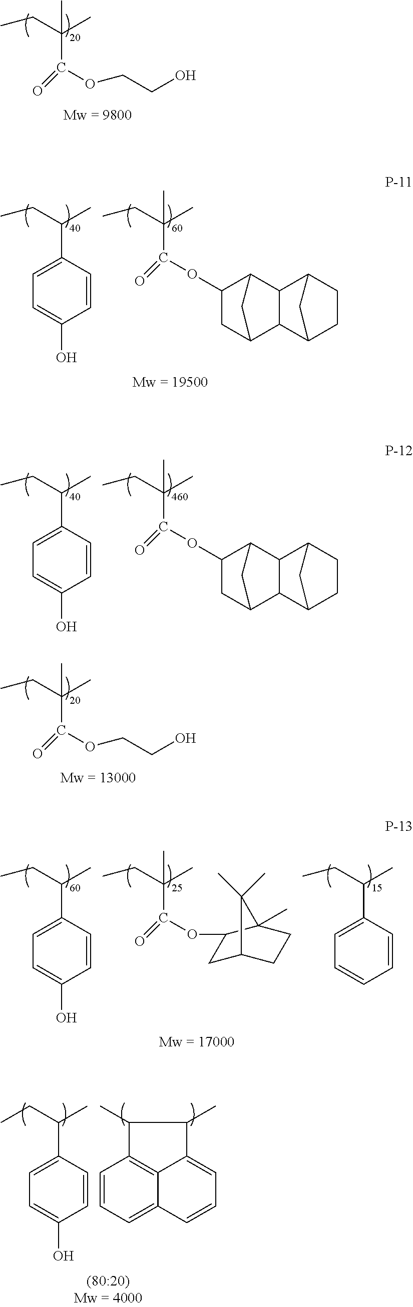

A content of the aromatic ring-containing compound (preferably, the polymer containing an aromatic ring, and more preferably, the novolac resin) in the composition for forming an underlayer film is preferably 10% to 100% by mass, more preferably 60% to 98% by mass, and still more preferably 80% to 95% by mass with respect to the total solid content of the composition for forming an underlayer film.

In the present specification, the solid content of the composition for forming an underlayer film is a component constituting the underlayer film, and is intended to be all components other solvent components (halogen-based organic solvent and non-halogen-based solvent) described later, in which a liquid component is regarded as the solid content. The solid content may be chemically changed from a state included in the composition for forming an underlayer film immediately before a timing of forming the underlayer film.

One kind of the aromatic ring-containing compound may be used singly, or two or more kinds thereof may be used.

<Halogen-Based Organic Solvent>

The composition for forming an underlayer film according to the embodiment of the present invention includes a halogen-based organic solvent (halogen-based organic solvent including one or more carbon atoms).

The halogen-based organic solvent is a liquid compound at normal temperature (25° C.), which includes a halogen atom (F, Cl, Br, I, and the like).

In addition, the halogen-based organic solvent has at least one carbon atom (preferably 1 to 15 carbon atoms).

Examples of the halogen-based organic solvent include chlorine-based organic solvents such as methylene chloride, chloroform, o-dichlorobenzene, m-dichlorobenzene, p-dichlorobenzene, 1,1-dichloroethane, 1,2-dichloroethane, 1,1,1-trichloroethane, 1,1,2-trichloroethane, carbon tetrachloride, trichloroethylene, and perchloroethylene; bromide-based organic solvents such as ethane bromide; fluorine-based organic solvents such as monofluorobenzene, 1,4-difluorobenzene, perfluoroheptane, perfluorooctane, benzotrifluoride, and dichloropentafluoropropane; and solvents including two or more halogen atoms, such as bromochloromethane and 1,2-dibromo-1,1-difluoroethane.

Among these, it is preferable that the halogen-based organic solvent includes one or more kinds selected from the group consisting of methylene chloride, chloroform, trichloroethylene, o-dichlorobenzene, and benzotrifluoride.

A content of the halogen-based organic solvent (preferably, methylene chloride, chloroform, trichloroethylene, o-dichlorobenzene, and/or benzotrifluoride) is 0.001 to 50 ppm by mass, preferably 0.01 to 10 ppm by mass and more preferably 0.02 to 1 ppm by mass with respect to the total mass of the composition for forming an underlayer film.

In addition, the content of the halogen-based organic solvent (preferably, methylene chloride, chloroform, trichloroethylene, o-dichlorobenzene, and/or benzotrifluoride) is preferably 0.01 to 300 ppm by mass, more preferably 0.05 to 100 ppm by mass, and still more preferably 0.1 to 10 ppm by mass with respect to the total content of the aromatic ring-containing compound (preferably, the polymer containing an aromatic ring, more preferably, the novolac resin, and still more preferably, the novolac resin having one or more repeating units represented by any of General Formula (A01), . . . , or (A06) described above). That is, a mass ratio (content of halogen-based organic solvent/content of aromatic ring-containing compound) of the content of the halogen-based organic solvent to the content of the aromatic ring-containing compound is preferably 0.01×10⁻⁶ to 300×10⁻⁶, more preferably 0.05×10⁻⁶ to 100×10^{0.6}, and still more preferably 0.1×10⁻⁶ to 10×10⁻⁶.

One kind of the halogen-based organic solvent may be used singly, or two or more kinds thereof may be used.

The type and content of the halogen-based organic solvent included in the composition for forming an underlayer film can be measured by, for example, the following method.

That is, first, using a heating adsorption device (manufactured by Markes International Ltd., M-CTE250), the solvent component in a sample (composition for forming an underlayer film) heated and vaporized at a heating temperature of 200° C., and adsorbed on a sample tube. Next, using a heat desorption device (manufactured by GL Sciences Inc., HandyTD TD265), the solvent component adsorbed on the sample tube is desorbed at a heating temperature of 200° C., and quantitative analysis of the desorbed solvent component with a gas chromatograph mass spectrometer (manufactured by JEOL Ltd., JMS-Q1500GC) to measure the type and content of the halogen-based organic solvent included in the composition for forming an underlayer film.

In addition, in a case where a formulation of the composition for forming an underlayer film is known, the type and content of the halogen-based organic solvent included in the composition for forming an underlayer film may be determined by calculation from the formulation amount.

<Crosslinking Agent>

The composition for forming an underlayer film according to the embodiment of the present invention may include a crosslinking agent.

In a case where the composition for forming an underlayer film includes a crosslinking agent, the underlayer film is likely to be cured at a lower temperature.

The crosslinking agent is a compound having a crosslinkable group which can react with the aromatic ring-containing compound to form a crosslinking structure. Among these, it is preferable that the crosslinking agent has a crosslinkable group that can react with the hydroxyl group (preferably, the aromatic hydroxyl group) which can be included in the aromatic ring-containing compound to form a crosslinking structure.

The crosslinking agent is preferably a compound having two or more (preferably 2 to 10) crosslinkable groups.

Examples of the crosslinkable group include a hydroxymethyl group, an alkoxymethyl group (methoxymethyl group and the like), an acyloxymethyl group, an alkoxymethyl ether group, an oxirane ring group, and an oxetane ring group.

It is preferable that the aromatic ring-containing compound and the crosslinking agent are different compounds. For example, it is preferable that the aromatic ring-containing compound does not have a crosslinkable group, and it is preferable to not have a hydroxymethyl group, an alkoxymethyl group (methoxymethyl group and the like), an acyloxymethyl group, an alkoxymethyl ether group, an oxirane ring group, and an oxetane ring group, and more preferable to not have an alkoxymethyl group (methoxymethyl group and the like).

Examples of the crosslinking agent include polynuclear phenols having a crosslinkable group (4-(2-{4-[1,1-bis(4-hydroxy-3,5-dimethoxymethylphenyl)ethyl]phenyl}propan-2-yl)-2,6-dimethoxymethylphenol and the like). In addition, examples of the crosslinking agent include diisocyanates, epoxy compounds, melamine-based curing agents (N,N,N′,N′,N″,N″-hexakis(methoxymethyl) melamine and the like), benzoguanamine-based curing agents, and glycoluril-based curing agents (1,3,4,6-tetrakis(methoxymethyl) glycoluril and the like).

A content of the crosslinking agent in the composition for forming an underlayer film is preferably 1% to 50% by mass, more preferably 5% to 30% by mass, and still more preferably 7% to 15% by mass with respect to the total solid content of the composition for forming an underlayer film.

One kind of the crosslinking agent may be used singly, or two or more kinds thereof may be used.

<Acid Generator>

The composition for forming an underlayer film according to the embodiment of the present invention may include an acid generator.

The acid generator may be a photoacid generator which generates acid in a case of being irradiated with light, may be a thermal acid generator by heating, or may have properties of both photoacid generator and thermal acid generator.

Among these, the acid generator is preferably a photoacid generator.

In a case where acid is generated from the acid generator, the crosslinking of the aromatic ring-containing compound (and the crosslinking agent) can be promoted.

In addition, by containing the acid generator, it is possible to eliminate inhibition of the crosslinking reaction in the underlayer film (problem of inactivating the acid in the underlayer film by a diffusion of substance (for example, bases such as OH—, CH₃—, and NH₂—) generated from a substrate (especially low dielectric film) into the underlayer film, thereby inhibiting the crosslinking reaction). That is, by reacting the generated acid in the formed underlayer film with an inhibitor, it is also possible to prevent the diffusion of the inhibitor into the underlayer film.

It is preferable that the aromatic ring-containing compound and the acid generator are different compounds. For example, it is preferable that the aromatic ring-containing compound is a compound which does not generate acid in a case of being exposed to light and/or heated, and it is also preferable that the aromatic ring-containing compound does not have a structure composed of a cation (particularly, an organic cation) and an anion (particularly, an organic anion).

The acid generator preferably includes a cation (onium cation) and an anion (acid anion).

The above-described cation preferably includes at feast one of an alicyclic structure, an aliphatic heterocyclic structure, or an aromatic ring structure having a chain substituent.

Examples of the above-described alicyclic structure include monocyclic cycloalkane structures such as a cyclopropane structure, a cyclobutane structure, a cyclopentane structure, and a cyclohexane structure; and polycyclic cycloalkane structures such as a norbornane structure and an adamantane structure.

Examples of the above-described aliphatic heterocyclic structure include monocyclic structures such as an oxirane structure, an oxetane structure, an oxolane structure, a thiolane structure, and a thiane structure; and polycyclic structures such as an oxanorbornane structure, an azanorbornane structure, a thianorbornane structure, a norbornane lactone structure, an oxanorbornane lactone structure, and a norbornane sultone structure.

Examples of the above-described aromatic ring structure having a chain substituent include structures in which a part or all of hydrogen atoms of an aromatic ring structure are substituted with chain hydrocarbon groups.

Examples of the above-described aromatic ring structure include a benzene structure, a naphthalene structure, an anthracene structure, and a phenalene structure.

Examples of the above-described chain hydrocarbon group include alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group.

The above-described cation is preferably a cation represented by any one of General Formula (C1), (C2), or (C3).

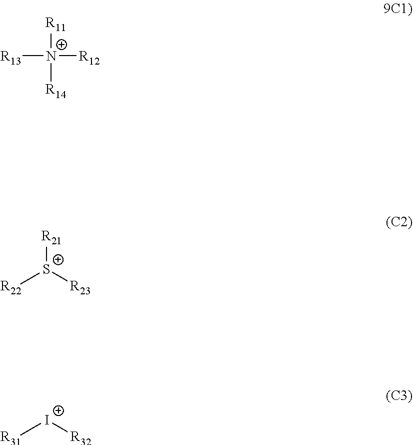

In General Formulae (C1) to (C3), R₁₁ to R₁₄, R₂₁ to R₂₃, R₃₁, and R₃₂ each independently represent a hydrogen atom, an alkyl group, or an aryl group.

Among these, it is preferable that three or four of R₁₁ to R₁₄ are the above-described alkyl group and/or the above-described aryl group, it is preferable that three of R₂₁ to R₂₃ are the above-described alkyl group and/or the above-described aryl group, and it is preferable that two of R₃₁ and R₃₂ are the above-described alkyl group and/or the above-described aryl group.

The number of carbon atoms in the above-described alkyl group is preferably 1 to 10. The above-described alkyl groups may be any of a primary alkyl group, a secondary alkyl group, or a tertiary alkyl group, respectively, and a primary alkyl group or a secondary alkyl group is preferable. The above-described alkyl groups may be linear or branched, respectively.

Examples of the above-described alkyl group include a methyl group, an ethyl group, an n-propyl group (n-propyl group and isopropyl group), and a butyl group (n-butyl group, sec-butyl group, isobutyl group, and tert-butyl group), which may have a substituent.

The above-described alkyl group may be used singly or in combination of two or more kinds thereof.

As the above-described aryl group, an aryl group having 6 to 15 carbon atoms is preferable, a phenyl group or a naphthyl group is more preferable, and a phenyl group is still more preferable.

The substituent which may be included in the above-described alkyl group and the above-described aryl group is not limited, and examples thereof include an organic group. Examples of the above-described organic group include an alicyclic hydrocarbon group (cycloalkyl group such as a cyclohexyl group, and the like).

In addition, as the substituent which may be included in the above-described aryl group, an alkyl group (preferably having 1 to 10 carbon atoms; may be linear or branched) is also preferable.

The above-described alkyl group and the above-described aryl group may be unsubstituted.

One kind of each of the above-described alkyl groups and the above-described aryl groups may be used singly, or two or more kinds thereof may be used.

In General Formula (C2), two of R₂₁ to R₂₃ may be bonded to each other to form a ring.

In a case where two of R₂₁ to R₂₃ are bonded to each other to form a ring, a ring skeleton may include a heteroatom such as an oxygen atom and a nitrogen atom. In one aspect, it is preferable that two of R₂₁ to R₂₃ are bonded to each other to form a ring, and two of R₂₁ to R₂₃ are jointly bonded to form an alkylene group (preferably having 3 to 7 carbon atoms) with both ends bonded to S⁺. In a case where two of R₂₁ to R₂₃ are bonded to each other to form a ring, it is also preferable that the remaining one of R₂₁ to R₂₃ is the above-described aryl group.

The above-described cation may be a cation represented by General Formula (Zal-4b).

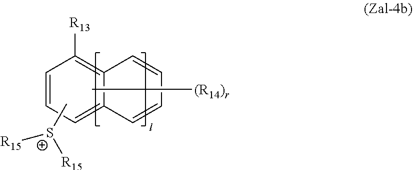

In General Formula (ZaI-4b),

l represents an integer of 0 to 2.

r represents an integer of 0 to 8.

R₁₃ represents a hydrogen atom, a fluorine atom, a hydroxyl group, an alkyl group, an alkoxy group, an alkoxycarbonyl group, or a group having a cycloalkyl group (which may be the cycloalkyl group itself or a group including the cycloalkyl group in a part thereof). These groups may have a substituent.

R₁₄ represents a hydroxyl group, an alkyl group, an alkoxy group, an alkoxycarbonyl group, an alkylcarbonyl group, an alkylsulfonyl group, a cycloalkylsulfonyl group, or a group having a cycloalkyl group (which may be the cycloalkyl group itself or a group including the cycloalkyl group in a part thereof). These groups may have a substituent. In a case where R₁₄'s are present in a plural number, R₁₄'s each independently represent the group such as a hydroxyl group.

R₁₅'s each independently represent an alkyl group, a cycloalkyl group, or a naphthyl group. These groups may have a substituent. Two R₁₅'s may be bonded to each other to form a ring. In a case where two R₁₅'s are bonded to each other to form a ring, a ring skeleton may include a heteroatom such as an oxygen atom and a nitrogen atom. In one aspect, it is preferable that two R₁₅'s are bonded to each other to form a ring, and two R₁₅'s are jointly bonded to form an alkylene group (preferably having 3 to 7 carbon atoms) with both ends bonded to S⁺.

In General Formula (ZaI-4b), the alkyl groups of R₁₃, R₁₄, and R₁₅ are linear or branched. The number of carbon atoms in the alkyl group is preferably 1 to 10. As the alkyl group, a methyl group, an ethyl group, an n-butyl group, or a t-butyl group is more preferable.

Examples of the above-described anion include an oxoacid anion and a sulfonylimide acid anion. Examples of the oxoacid anion include a sulfonate anion, a carboxylate anion, and a phosphonate anion. Among these, from the viewpoint of strength of the generated acid, a sulfonate anion is preferable.

As the above-described sulfonate anion, an anion represented by General Formula (2-a) is preferable.

R³—SO₃⁻ (2-a)

In General Formula (2-a), R³ represents an organic group and is preferably an organic group having 1 to 20 carbon atoms.

Examples of the organic group (preferably, the organic group having 1 to 20 carbon atoms) of R³ include a monovalent hydrocarbon group, a group including a heteroatom-containing group between carbons of the hydrocarbon group, and a group in which a part or all of hydrogen atoms in these groups are substituted with substituents.

Examples of the above-described monovalent hydrocarbon group include a chain hydrocarbon group, an alicyclic hydrocarbon group, an aromatic hydrocarbon group, and a combination of these groups.

Examples of the above-described chain hydrocarbon group include alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group.

Examples of the above-described alicyclic hydrocarbon group include cycloalkyl groups such as a cyclopropyl group, a cyclopentyl group, a cyclohexyl group, a norbornyl group, and an adamantyl group; and cycloalkenyl groups such as a cyclopropenyl group, a cyclopentenyl group, a cyclohexenyl group, and a norbornenyl group.

Examples of the above-described aromatic hydrocarbon group include aryl groups such as a phenyl group, a tolyl group, a xylyl group, a naphthyl group, and an anthryl group; and aralkyl groups such as a benzyl group, a phenethyl group, and a naphthylmethyl group.

The above-described heteroatom-containing group refers to, for example, a group having a divalent or higher valent heteroatom in the structure. The above-described heteroatom-containing group may have one heteroatom or two or more heteroatoms.

The divalent or higher heteroatom included in the above-described heteroatom-containing group is not particularly limited as long as it is a heteroatom having a divalent or higher valence, and examples thereof include an oxygen atom, a nitrogen atom, a sulfur atom, a silicon atom, a phosphorus atom, and a boron atom.

Examples of the above-described heteroatom-containing group include groups consisting of only heteroatoms, such as —SO—, —SO₂—, —SO₂O—, and —SO₃—; and groups of a combination of carbon atom and heteroatom, such as —CO—, —COO—, —COS—, —CONH—, —OCOO—, —OCOS—, —OCONH—, —SCONH—, —SCSNH—, and —SCSS—.

Examples of the above-described substituent include a halogen atom, a hydroxyl group, a carboxyl group, a nitro group, and a cyano group.

Among these, as R³, a hydrocarbon group having a halogen atom is preferable, a hydrocarbon group having a fluorine atom is more preferable, and a hydrocarbon group which has 1 to 6 carbon atoms and has a fluorine atom is still more preferable.

Among these, the sulfonate anion is more preferably an anion represented by General Formula (A1).

Rf—SO₃^{⊖} (A1)

In General Formula (A1), Rf represents an organic group having one or more fluorine atoms. Examples of the organic group in the above-described organic group having one or more fluorine atoms include the same group as the organic group of R³ in General Formula (2-a) described above.

Among these, the number of fluorine atoms included in the above-described organic group having one or more fluorine atoms is preferably 1 to 20 and more preferably 2 to 12.

Among these, Rf is preferably a fluoroalkyl group (linear or branched fluoroalkyl group) and more preferably a perfluoroalkyl group. The number of carbon atoms in Rf is preferably 1 to 20 and more preferably 1 to 5.

Among these, the acid generator is preferably a compound represented by any one of General Formula (1), (2), or (3).

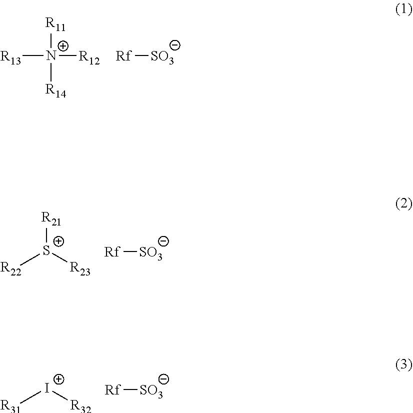

In General Formulae (1) to (3), R₁₁ to R₁₄, R₂₁ to R₂₃, R₃₁, and R₃₂ each independently represent a hydrogen atom, an alkyl group, or an aryl group. Rf represents an organic group having one or more fluorine atoms.

In General Formula (2), two of R₂₁ to R₂₃ may be bonded to each other to form a ring.

The cations in General Formulae (1) to (3) correspond to the cations represented by General Formulae (C1) to (C3), respectively.

The anions in General Formulae (1) to (3) correspond to the anion represented by General Formula (A1).

As a lower limit of the sum of atomic weights of the atoms constituting the anion, 150 or more is preferable, 180 or more is more preferable, and 190 or more is still more preferable. On the other hand, as an upper limit of the sum of atomic weights described above, 350 or less is preferable, 320 or less is more preferable, and 300 or less is still more preferable. In a case where the sum of atomic weights described above is within the above-described range, a diffusion length of the acid generated from the acid generator tends to be within an appropriate range.

As the acid generator in the composition for forming an underlayer film, a photoacid generator which can be included in a resist composition described later can also be used in the same manner.

In addition, as the cation of the acid generator in the composition for forming an underlayer film, a cation in the photoacid generator which can be included in the resist composition described later can also be used in the same manner.

In addition, as the anion of the acid generator in the composition for forming an underlayer film, an anion in the photoacid generator which can be included in the resist composition described later can also be used in the same manner.

As the photoacid generator, for example, compounds described in paragraphs 0076 to 0081 of WO2007/105776A can also be used.

Examples of the photoacid generator include diphenyliodonium trifluoromethanesulfonate, diphenyliodonium nonafluoro-n-butanesulfonate, diphenyliodonium pyrene sulfonate, diphenyliodonium n-dodecylbenzene sulfonate, diphenyliodonium 10-camphorsulfonate, diphenyliodonium naphthalene sulfonate, bis(4-t-butylphenyl)iodonium trifluoromethanesulfonate, bis(4-t-butylphenyl)iodonium nonafluoro-n-butanesulfonate, bis(4-t-butylphenyl)iodonium n-dodecylbenzenesulfonate, bis(4-t-butylphenyl)iodonium 10-camphorsulfonate, and bis(4-t-butylphenyl)iodonium naphthalene sulfonate.

These photoacid generators may have characteristics as the thermal acid generator.

Examples of the thermal acid generator include 2,4,4,6-tetrabromocyclohexadienone, benzoin tosylate, 2-nitrobenzyltosylate, and alkylsulfonates. These thermal acid generators may have characteristics as the photoacid generator.

Structures of the acid generator are shown below.

In addition, an acid generator in which the cation and the anion used in the following acid generators are appropriately modified may be used.

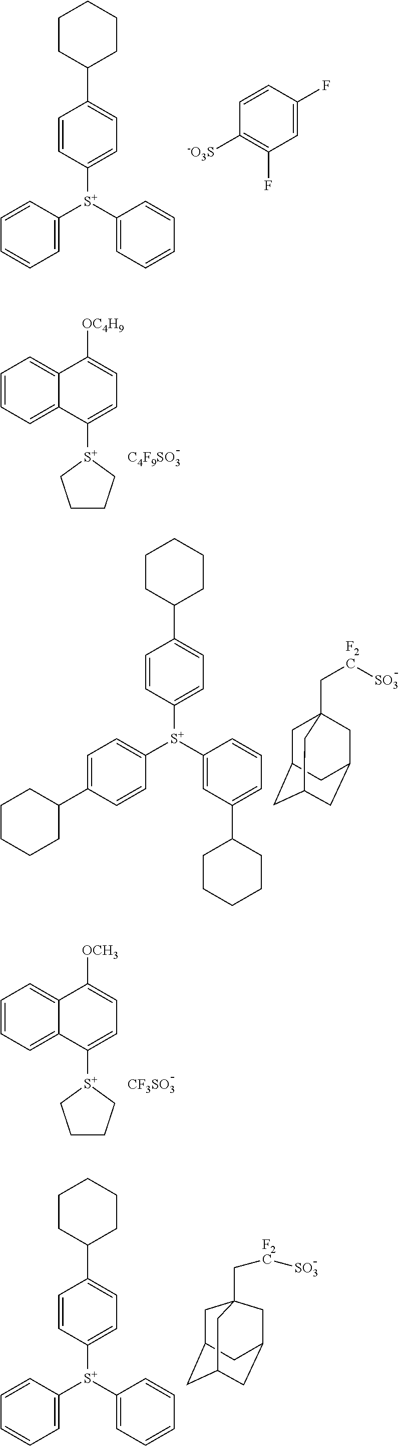

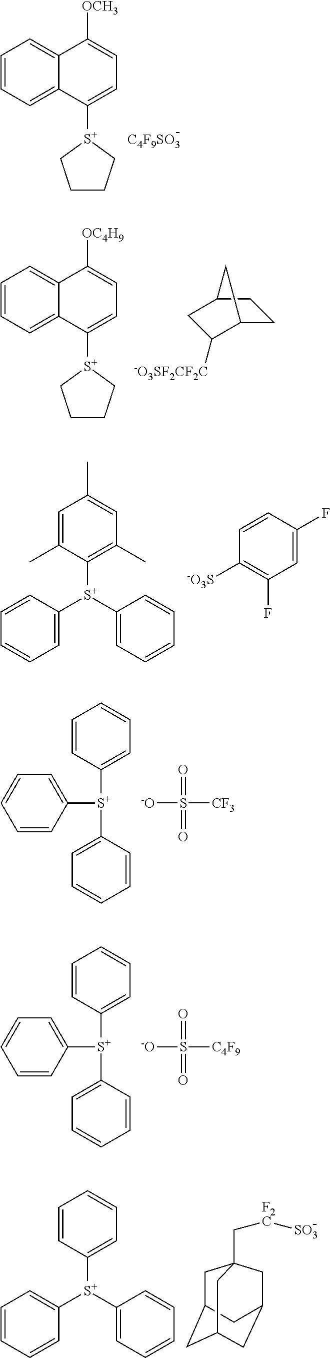

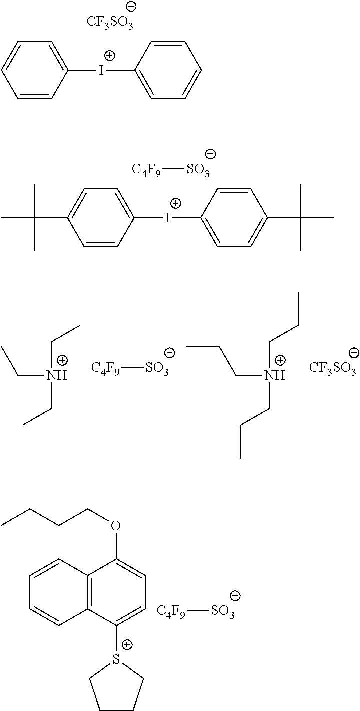

A content of the acid generator in the composition for forming an underlayer film is preferably 0.1% to 30%.by mass, more preferably 0.5% to 20% by mass, and still more preferably 1% to 12% by mass with respect to the total solid content of the composition for forming an underlayer film.

The acid generator may be used singly or in combination of two or more kinds thereof.

<Solvent>

The composition for forming an underlayer film may include a solvent.

The solvent referred to here is a non-halogen-based solvent different from the above-described halogen-based organic solvent.

Examples of the solvent include organic solvents (non-halogen-based organic solvent) and water.

(Organic Solvent)

Examples of the organic solvent include organic solvents such as an alcohol-based solvent, an ether-based solvent, a ketone-based solvent, an amide-based solvent, an ester-based solvent, and a hydrocarbon-based solvent.

Examples of the above-described alcohol-based solvent include aliphatic monoalcohol-based solvents having 1 to 18 carbon atoms, such as 4-methyl-2-pentanol and n-hexanol; alicyclic monoalcohol-based solvents having 3 to 18 carbon atoms, such as cyclohexanol; polyhydric alcohol-based solvents having 3 to 18 carbon atoms, such as 1,2-propylene glycol; and polyhydric alcohol-partially ether-based solvents having 3 to 19 carbon atoms, such as propylene glycol monoethyl ether.

Examples of the above-described ether-based solvent include dialiphatic ether solvents such as diethyl ether, dipropyl ether, and dibutyl ether; aromatic ring-containing ether-based solvents such as anisole and diphenyl ether; and cyclic ether-based solvents such as tetrahydrofuran and dioxane.

Examples of the above-described ketone-based solvent include chain ketone-based solvents such as acetone, methyl ethyl ketone, methyl-n-propyl ketone, methyl-n-butyl ketone, diethyl ketone, methyl-iso-butyl ketone, methyl-n-amyl ketone, ethyl-n-butyl ketone, methyl-n-hexyl ketone, di-iso-butyl ketone, trimethyl nonanone, and acetophenone; cyclic ketone-based solvents such as cyclopentanone, cyclohexanone, cycloheptanone, cyclooctanone, and methylcyclohexanone; and diketone-based solvents such as 2,4-pentandione and acetylacetone.

Examples of the above-described amide-based solvent include chain amide-based solvents such as N-methylformamide, N,N-dimethylformamide, N,N-diethylformamide, acetamide, N-methylacetamide, N,N-dimethylacetamide, and N-methylpropionamide; and cyclic amide-based solvents such as N-methylpyrrolidone and N,N′-dimethylimidazolidinone.

Examples of the above-described ester-based solvent include monocarboxylic acid ester solvents such as n-butyl acetate and ethyl lactate; lactone-based solvents such as y-butyrolactone and valero lactone; polyhydric alcohol-partially ether carboxylate-based solvents such as propylene glycol monomethyl ether acetate; polyvalent carboxylic acid diester-based solvents such as diethyl oxalate; and carbonate-based solvents such as dimethyl carbonate and diethyl carbonate.

Examples of the above-described hydrocarbon-based solvent include aliphatic hydrocarbon-based solvents such as n-pentane, iso-pentane, n-hexane, iso-hexane, n-heptane, iso-heptane, 2,2,4-trimethylpentane, n-octane, iso-octane, cyclohexane, and methylcyclohexane; and aromatic hydrocarbon-based solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene, and n-amylnaphthalene.

Among these, as the organic solvent, an alcohol-based solvent, an ester-based solvent, or a ketone-based solvent is preferable, a polyhydric alcohol-partially ether-based solvent, a polyhydric alcohol monoalkyl ether acetate-based solvent, or a cyclic ketone-based solvent is more preferable, and propylene glycol monoethyl ether, propylene glycol monomethyl ether acetate, or cyclohexanone is still more preferable.

A content of the organic solvent is preferably 70% to 100% by mass, more preferably 90% to 100% by mass, and still more preferably 99% to 100% by mass with respect to the total mass of the solvent (non-halogen-based solvent).

One kind of the organic solvent may be used singly, or two or more kinds thereof may be used.

(Water)

The composition for forming an underlayer film may include water.

In a case where the composition for forming an underlayer film includes water, a content of the water is preferably 0.1% to 30% by mass, more preferably 0.2% to 20% by mass, and still more preferably 0.2% to 15% by mass with respect to the total mass of the composition for forming an underlayer film.

The content of the solvent is an amount in which a concentration of solid contents in the composition for forming an underlayer film is preferably 0.1% to 60% by mass, more preferably 0.5% to 20% by mass, and still more preferably 1% to 10% by mass.

<Other Components>

In addition to the above-described components, the composition for forming an underlayer film may include other components such as an acidic compound, a basic compound, a thermosetting polymer, a radiation absorber, a storage stabilizer, a defoamer, and/or an adhesive aid.

<Method for Preparing Composition for Forming Underlayer Film>

A method for preparing the composition for forming an underlayer film is not limited, and for example, the composition for forming an underlayer film is obtained by mixing the aromatic ring-containing compound, the halogen-based organic solvent, and optionally other components.

[Resist Pattern Forming Method]

A resist pattern forming method according to an embodiment of the present invention includes the following steps (O) to (S).

(O) step (underlayer film forming step) of forming an underlayer film on a substrate by using the composition for forming an underlayer film

(P) step (second underlayer film forming step) of forming a second underlayer film on the substrate by using a composition for forming a second underlayer film

(Q) step (resist film forming step) of forming a resist film on the second underlayer film by using a resist composition

(R) step (exposing step) of exposing the resist film

(S) step (developing step) of developing the exposed resist film with a developer to form a resist pattern

In the step (O), the underlayer film may be formed directly on the substrate, or may be formed through other layers. In the step (P), the second underlayer film may be formed directly on the underlayer film, or may be formed through other layers. In the step (Q), the resist film may be formed directly on the second underlayer film, or may be formed through other layers.

In addition, the step (P) may be omitted, and in this case, a resist film is formed on the underlayer film in the step (Q).

<Step O (Underlayer Film Forming Step)>

A material of the substrate in the step (O) is not particularly limited, and examples thereof include inorganic substrates of silicon, SiN, SiO₂, SiN, and the like; and substrates commonly used in semiconductor manufacturing processes such as IC, circuit board manufacturing processes such as liquid crystal and thermal head, and other lithography processes of photofabrication.

Among these, the substrate is preferably a silicon (Si) substrate.

In addition, the substrate may be a stepped substrate. The stepped substrate is a substrate on which at least one stepped shape is formed.

In a case where the substrate is a stepped substrate, a film thickness of the underlayer film means a height from a bottom surface of the stepped substrate to an upper surface of the formed underlayer film.

For example, in an aspect of injecting ions into the substrate, as the stepped substrate, a substrate in which fins and/or gates are patterned on a flat substrate can be used. In a case where the underlayer film is formed on the stepped substrate on which the fins and/or gates are patterned, a film thickness of the formed underlayer film does not mean a height from an upper surface of the fins and gates to an upper surface of the formed underlayer film, but a height from a bottom surface of the stepped substrate to an upper surface of the formed underlayer film, as described above.

As the size (width, length, height, and the like), spacing, structure, configuration, and the like of the fins and gates, for example, the description in pages 25 to 29 of “Cutting-edge FinFET processing and integration technology” Journal of the institute of Electronics, Information and Communication Engineers Vol. 91 No. 1 2008, or Jpn. J. Appl. Phys. Vol. 42 (2003) pp. 4142-4146 Part1 No. 6B June 2003 “Fin-Type Double-Gate Metal-Oxide-Semiconductor Field-Effect Transistors Fabricated by Orientation-Dependent Etching and Electron Beam Lithography” can be referred to.

Examples of the stepped substrate include a stepped substrate having a groove portion in which a groove width is an exposure wavelength or less (preferably 100 nm or less and more preferably 40 nm or less; usually 15 nm or more) and a depth is 200 nm or less (preferably 50 to 200 nm and more preferably 65 to 200 nm), and a stepped substrate having a cylindrical recess portion in which a diameter is an exposure wavelength or less (preferably 100 nm or less and more preferably 40 nm or less; usually 15 nm or more) and a depth is 100 nm or less (preferably 50 to 100 nm and more preferably 65 to 100 nm).

Examples of the stepped substrate having the above-described groove portion include a stepped substrate having a plurality of grooves repeatedly at equal intervals, for example, at a pitch of 20 to 200 nm (preferably 50 to 200 nm and more preferably 70 to 150 nm).

In addition, examples of the stepped substrate having the above-described cylindrical recess portion include a stepped substrate having a plurality of cylindrical recess portions repeatedly at equal intervals, for example, at a pitch of 20 to 200 nm (preferably 50 to 150 nm and more preferably 70 to 120 nm).

The underlayer film corresponds to a so-called spin on carbon (SOC) layer.

The underlayer film is formed the above-described substrate by using the above-described composition for forming an underlayer film.

Examples of a specific method thereof include a method in which the composition for forming an underlayer film is applied to the substrate by using a spin coating method, spray method, roller coating method, a dipping method, or the like, which is known in the related art.

In a case where the composition for forming an underlayer film includes the solvent, it is preferable to volatilize the solvent from a coating film obtained by applying the composition for forming an underlayer film.

The coating film may be subjected to a heating treatment and/or exposure treatment as desired, so that the aromatic ring-containing compound (preferably, the novolac resin) is crosslinked by such a treatment.

After applying the composition for forming an underlayer film, the solvent in the coating film may be volatilized by pre-baking (PB) as desired, separately from a heating treatment described later. A temperature of PB is preferably 30° C. to 200° C. In addition, a time of PB is preferably 5 to 600 seconds.

A lower limit of a heating temperature in the heating treatment is preferably 100° C. or higher, more preferably 120° C. or higher, still more preferably 150° C. or higher, and particularly preferably 200° C. or higher. On the other hand, an upper limit of the heating temperature described above is preferably 450° C. or lower, more preferably 400° C. or lower, still more preferably 300° C. or lower, and particularly preferably 280° C. or lower.

A lower limit of a heating time in the heating treatment is preferably 10 seconds or more, more preferably 15 seconds or more, still more preferably 20 seconds or more, and particularly preferably 40 seconds or more. On the other hand, an upper limit of the heating time described above is preferably 1 hour or less, more preferably 10 minutes or less, still more preferably 150 seconds or less, and particularly preferably 80 seconds or less.

In addition, an atmosphere during the above-described heating treatment is not particularly limited, and the heating treatment may be performed under an air atmosphere or under an inert gas atmosphere of nitrogen gas and the like.

In the exposure treatment, a ultraviolet (UV) lamp, light irradiation with visible light, or the like is used. Examples of a light source include a mercury lamp, a metal halide lamp, a xenon lamp, a chemical lamp, and a carbon arc lamp. Examples of radiation include electron beams, X-rays, ion beams, and far infrared rays. Examples of a specific aspect include scanning exposure with infrared laser, high-illuminance flash exposure with xenon discharge lamp and the like, and infrared lamp exposure.

A film thickness of the formed underlayer film is preferably 0.01 to 30 μm, more preferably 0.05 to 10 μm, and still more preferably 0.1 to 2 μm.

The underlayer film preferably has a function of improving pattern resolution of the resist film and a function of transferring the resist pattern formed on the upper layer to the substrate while maintaining a pattern shape in good condition.

Examples of one aspect of assisting the pattern resolution of the resist film include an optical function in which, by controlling a refractive index and extinction coefficient of the underlayer film at an exposure wavelength, reflection from a substrate side during exposure is appropriately controlled in a lithography process, so that a good shape of an optical image formed during the exposure is maintained. In addition, examples of the function of the underlayer film also include a function of, in a case of transferring the pattern shape to the substrate, maintaining good mask performance as an etching mask for etching under appropriately selected conditions according to thicknesses of the resist film (resist pattern) formed on the upper layer, the underlayer film, and the substrate and to an etching rate.

As a method for improving reflection characteristic during the exposure, for example, in a mask exposure process, based on exposure information including a pattern shape and transmittance of the mask, exposure intensity, polarization and shape of a projection light source, and the like, by adjusting the exposure information with simulation software known by a trade name of PROLITH (manufactured by KLA Tencor), the reflection characteristic at the exposure wavelength can be improved. For example, target design information such as refractive index n value and extinction coefficient k value of the underlayer film, and the film thickness of the underlayer film, which are used for maintaining rectangularity of the optical image during the exposure, are obtained, and by using an appropriate resin structure and additives such as a crosslinking agent for the obtained target, good reflection characteristic and resolution can be obtained. A preferred range of the refractive index n value of the underlayer film is preferably 1.2 to 3.0. In addition, a preferred range of the extinction coefficient k value of the underlayer film is preferably 0.05 to 1.0.

In addition, in the lithography process on the Processed substrate, it is necessary to form a flat underlayer film on the substrate having an uneven structure, and a function of satisfying gap fill property and flatness after application is also strongly required.

It is also possible to form an organic antireflection film on the substrate, and then form the underlayer film thereon. As the organic antireflection film, for example, films described in JP1994-12452B (JP-H6-12452B), JP1984-93448A (JP-S59-93448A), and the like can be used.

<Step P (Second Underlayer Film Forming Step)>

In the second underlayer film forming step, a second underlayer film is formed on the above-described underlayer film by using a composition for forming a second underlayer film.

The second underlayer film is, for example, a spin on glass (SOG) layer. The composition for forming a second underlayer film is, for example, a composition for forming the SOG layer.

The composition for forming a second underlayer film is preferably a composition including a silicon atom-containing compound (preferably, polysiloxane). In addition, the composition for forming a second underlayer film preferably includes a solvent (preferably, an organic solvent).

As the composition for forming a second underlayer film, for example, compositions for forming a silicon-containing film, described in paragraph 0093 and later of JP2013-076973A, polysiloxane compositions for forming a resist underlayer film, described in JP2016-27370A, or the like can be adopted.

In a case where the composition for forming a second underlayer film includes a solvent, it is preferable to volatilize the solvent from a coating film obtained by applying the composition for forming a second underlayer film.

The coating film may be subjected to a heating treatment as desired, so that the silicon atom-containing compound (preferably, the polysiloxane) is crosslinked by the heating treatment.

Examples of a method of applying the composition for forming a second underlayer film include a spin coating, a cast coating, and a roll coating.

A lower limit of a film thickness (average film thickness) of the formed second underlayer film is preferably 0.01 μm or more. On the other hand, an upper limit of the above-described film thickness (average film thickness) is preferably 1 μm or less and more preferably 0.5 μm or less.

After applying the composition for forming a second underlayer film, the solvent in the coating film may be volatilized by pre-baking (PB) as desired, separately from a heating treatment described later. A temperature of PB is preferably 30° C. to 200° C. In addition, a time of PB is preferably 5 to 600 seconds.

A lower limit of a heating temperature in the heating treatment is preferably 100° C. or higher, more preferably 120° C. or higher, still more preferably 150° C. or higher, and particularly preferably 200° C. or higher. On the other hand, an upper limit of the heating temperature described above is preferably 450° C. or lower, more preferably 400° C. or lower, still more preferably 300° C. or lower, and particularly preferably 240° C. or lower.

A lower limit of a heating time in the heating treatment is preferably 10 seconds or more, more preferably 15 seconds or more, still more preferably 20 seconds or more, and particularly preferably 40 seconds or more. On the other hand, an upper limit of the heating time described above is preferably 1 hour or less, more preferably 10 minutes or less, still more preferably 150 seconds or less, and particularly preferably 80 seconds or less.

In addition, an atmosphere during the above-described heating treatment is not particularly limited, and the heating treatment may be performed under an air atmosphere or under an inert gas atmosphere of nitrogen gas and the like.

<Step Q (Resist Film Forming Step)>

In the resist film forming step, a resist film is formed on the above-described second underlayer film by using a resist composition.

The resist composition will be described later.

Examples of the method of forming the resist film on the substrate by using the resist composition include a method (coating method) in which the resist composition is applied to the second underlayer film, and as necessary, a curing treatment is performed, and a method in which the resist film is formed on a temporary support, and the resist film is transferred to the substrate (to the second underlayer film). Among these, from the viewpoint of excellent productivity, the coating method is preferable.

In the coating method, the resist composition can be applied by an appropriate coating method of a spinner, a coater, and the like. The coating method is preferably a spin coating using a spinner. A rotation speed in a case of the spin coating using a spinner is preferably 1000 to 3000 rpm.

After the application of the resist composition, the coating film of the resist composition may be dried to form the resist film.

Examples of a drying method include a method of performing drying by heating. The heating can be performed using a unit included in an ordinary exposure machine and/or development machine, or may also be performed using a hot plate or the like. A heating temperature is preferably 80° C. to 150° C., more preferably 80° C. to 140° C., and still more preferably 80° C. to 130° C. A heating time is preferably 30 to 1000 seconds, more preferably 60 to 800 seconds, and still more preferably 60 to 600 seconds.

A film thickness of the resist film is not particularly limited, but from the viewpoint that a more accurate fine pattern can be formed, the film thickness is preferably 1 to 1000 mu, more preferably 10 to 700 mu, and still more preferably 15 to 150 nm.

A topcoat may be formed on the upper layer of the resist film, using a topcoat composition.

It is preferable that the topcoat composition is not mixed with the resist film and can be uniformly applied to the upper layer of the resist film.

In addition, it is preferable that the resist film is dried before forming the topcoat. Subsequently, the topcoat composition is applied to the obtained resist film by the same unit as for the method of forming the resist film, and further dried to form the topcoat.

A film thickness of the topcoat is preferably 10 to 200 nm, more preferably 20 to 100 nm, and still more preferably 40 to 80 nm.

The topcoat is not particularly limited, a topcoat known in the related art can be formed by the methods known in the related art, and the topcoat can be formed, based on the description in paragraphs 0072 to 0082 of JP2014-059543A, for example.

For example, it is preferable that a topcoat including a basic compound, as described in JP2013-61648A, is formed on the resist film. Specific examples of the basic compound which can be included in the topcoat also include a basic compound which may be included in the resist composition.

In addition, the topcoat preferably includes a compound which includes at least one group or bond selected from the group consisting of an ether bond, a thioether bond, a hydroxyl group, a thiol group, a carbonyl bond, and an ester bond.

For the purpose of reducing a peeling and collapse of the resist pattern, an adhesion auxiliary layer may be provided between the second underlayer film and the resist film. In the step (Q) in this case, the resist film is formed on the adhesion auxiliary layer. In other words, in the step (Q) in this case, the resist film is formed on the second underlayer film through the adhesion auxiliary layer.

Examples of a method for forming the adhesion auxiliary layer include a method for forming an adhesion auxiliary layer having a polymerizable group on the second underlayer film. The polymerizable group in the adhesion auxiliary layer formed by this method forms a chemical or physical bond with the second underlayer film and/or the resist film and the like. As a result, it is considered that excellent adhesiveness is exhibited between the second underlayer film and the resist film.

The adhesion auxiliary layer preferably has a polymerizable group. More specifically, it is preferable that a material forming the adhesion auxiliary layer (particularly, a resin is preferable) has a polymerizable group.

The type of the polymerizable group is not particularly limited, and examples thereof include a (meth)acryloyl group, an epoxy group, an oxetanyl group, a maleimide group, an itaconic acid ester group, a crotonic acid ester group, an isocrotonic acid ester group, a maleic acid ester group, a styryl group, a vinyl group, an acrylamide group, and an methacrylamide group. Among these, a (meth)acryloyl group, an epoxy group, an oxetanyl group, or a maleimide group is preferable, and a (meth)acryloyl group is more preferable.

A thickness of the adhesion auxiliary layer is not particularly limited, but from the reason that a more accurate fine pattern can be formed, is preferably 1 to 100 nm, more preferably 1 to 50 nm, still more preferably 1 to 10 nm, and particularly preferably 1 to 5 nm.

The method for forming the above-described adhesion auxiliary layer is not particularly limited, and examples thereof include a method (coating method) in which a composition for forming an adhesion auxiliary layer is applied to the second underlayer film, and as necessary, a curing treatment is performed to form the above-described adhesion auxiliary layer, and a method in which the adhesion auxiliary layer is formed on a temporary support, and the adhesion auxiliary layer is transferred to the substrate to the second underlayer film. Among these, from the viewpoint of excellent productivity, the coating method is preferable.

A method for applying the composition for forming an adhesion auxiliary layer to the second underlayer film is not particularly limited, and a known method can be used. Examples thereof include a spin coating method.

After the composition for forming an adhesion auxiliary layer is applied to the second underlayer film, as needed, a curing treatment may be performed. The curing treatment is not particularly limited, and examples thereof include an exposure treatment and a heating treatment.

In the exposure treatment, a UV lamp, light irradiation with visible light, or the like is used. Examples of a light source include a mercury lamp, a metal halide lamp, a xenon lamp, a chemical lamp, and a carbon arc lamp. Examples of radiation include electron beams, X-rays, ion beams, and far infrared rays. Examples of a specific aspect include scanning exposure with infrared laser, high-illuminance flash exposure with xenon discharge lamp and the like, and infrared lamp exposure.

An exposure time varies depending on reactivity of the polymer and a light source, but is usually 10 seconds to 5 hours. An exposure energy is preferably 10 to 10000 mJ/cm² and more preferably 100 to 8000 mJ/cm².

In addition, in a case of using a heating treatment, a blast dryer, an oven, an infrared dryer, and/or a heating drum can be used.

The exposure treatment and the heating treatment may be combined.

(Resist Composition)

The resist composition may be a positive resist composition or a negative resist composition.

In addition, the resist composition is typically a chemically amplified resist composition.

Hereinafter, each component of the resist composition which can be suitably used in the pattern forming method according to the embodiment of the present invention will be described.

Resin (A)

The resist composition usually includes a resin (also simply referred to as a resin (A)).

The resin (A) preferably has a repeating unit having an acid-decomposable group.

Here, the acid-decomposable group refers to a group which is decomposed by the action of an acid and generates a polar group.

The acid-decomposable group preferably has a structure in which a polar group is protected with a group (leaving group) that is eliminated through decomposition by the action of an acid.

Examples of the polar group include an acidic group (a group which dissociates in a 2.38%-by-mass tetramethylammonium hydroxide aqueous solution), such as a phenolic hydroxyl group, a carboxyl group, a fluorinated alcohol group (preferably, a hexafluoroisopropanol group), a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

The alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol group (for example, a fluorinated alcohol group (hexafluoroisopropanol group and the like)) having the α-position substituted with an electron withdrawing group such as a fluorine atom is excluded as a hydroxyl group. The alcoholic hydroxyl group is preferably a hydroxyl group having a pKa (acid dissociation constant) of 12 to 20.

Preferred examples of the polar group include a carboxyl group, a fluorinated alcohol group (preferably, a hexafluoroisopropanol group), and a sulfonic acid group.

The preferred group as the acid-decomposable group is a group in which the hydrogen atom of these groups is substituted with a group eliminated by acid.

Examples of the group (leaving group) eliminated by acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the acid-decomposable group, a cumyl ester group, an enol ester group, an acetal ester group, a tertiary alkyl ester group, or the like is preferable, and a tertiary alkyl ester group is more preferable.

The resin (A) preferably has a repeating unit represented by General Formula (AI) as the repeating unit having an acid-decomposable group. The repeating unit represented by General Formula (AI) generates a carboxyl group as the polar group by the action of an acid.

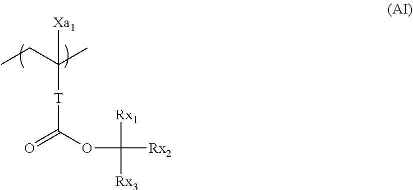

In General Formula (AI),

Xa₁ represents a hydrogen atom, an alkyl group, a cyano group, or a halogen atom.

T represents a single bond or a divalent linking group.

Rx₁ to Rx₃ each independently represent an alkyl group or a cycloalkyl group.

Two of Rx₁ to Rx₃ may be bonded to each other to form a ring structure.

In addition, as the repeating unit having an acid-decomposable group, the resin (A) also preferably has a repeating unit having a structure protected by the leaving group, in which the phenolic hydroxyl group is decomposed and eliminated by the action of an acid. In the present specification, the phenolic hydroxyl group is a group obtained by substituting a hydrogen atom of an aromatic hydrocarbon group with a hydroxyl group. The aromatic ring of the aromatic hydrocarbon group is a monocyclic or polycyclic aromatic ring, and examples thereof include a benzene ring and a naphthalene ring.

As the repeating unit having the structure protected by the leaving group, in which the phenolic hydroxyl group is decomposed and eliminated by the action of an acid, a repeating unit represented by General Formula (AII) is preferable.

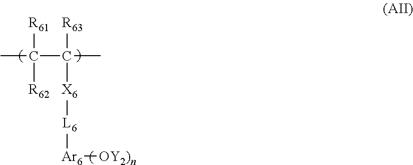

In General Formula (AII),

R₆₁, R₆₂, and R₆₃ each independently represent a hydrogen atom, an alkyl group, a cycloalkyl group, a halogen atom, a cyano group, or an alkoxycarbonyl group. However, R₆₂ may be bonded to Ar₆ to form a ring, and in this case, R₆₂ represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1)-valent aromatic hydrocarbon group, and in a case of being bonded to R₆₂ to form a ring, Ar₆ represents an (n+2)-valent aromatic hydrocarbon group.

In a case where n≥2, Y₂'s each independently represent a hydrogen atom or a group eliminated due to the action of an acid. However, at least one of Y₂'s represents the group eliminated due to the action of an acid. As the group eliminated due to the action of an acid as Y₂, the group described as the leaving group is preferable.

n represents an integer of 1 to 4.

Each of the above-described groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), and these groups preferably have 8 or less carbon atoms.

The repeating unit having an acid-decomposable group may be used alone or in combination of two or more kinds thereof.

A content of the repeating unit having an acid-decomposable group included in the resin (A) (in a case where a plurality of the repeating units having an acid-decomposable group are present, a total content thereof) is preferably 20 to 90 mol % and more preferably 40 to 80 mol % with respect to all the repeating units of the resin (A). Among these, it is preferable that the resin (A) has the above-described repeating unit represented by General Formula (AI), and it is more preferable that the content of the above-described repeating unit represented by General Formula (AI) is 40 mol % or more with respect to all repeating units of the resin (A).

The resin (A) preferably has at least one selected from the group consisting of a lactone structure, a sultone structure, and a carbonate structure, and more preferably has a repeating unit having at least one selected from the group consisting of a lactone structure, a sultone structure, and a carbonate structure.

Any lactone structure or sultone structure can be used as long as the structure has a lactone structure or a sultone structure, but a 5- to 7-membered ring lactone structure or a 5- to 7-membered ring sultone structure is preferable, and a structure in which another ring structure is fused to a 5- to 7-membered ring lactone structure so as to form a bicyclo structure and/or a spiro structure, or a structure in which another ring structure is fused to a 5- to 7-membered ring sultone structure so as to form a bicyclo structure and/or a spiro structure is more preferable. It is even more preferable that the resin (A) has a repeating unit having a lactone structure represented by any of General Formula (LC1-1), . . . , (LC1-21) or a sultone structure represented by any of General Formula (SL1-1), (SL1-2), or (SL1-3). In addition, the lactone structure or the sultone structure may be bonded directly to the main chain.

Among these, as the lactone structure, a lactone structure represented by General Formula (LC1-1), (LC1-4), (LC1-5), (LC1-6), (LC1-13), (LC1-14), or (LC1-17) is preferable, and a lactone structure represented by General Formula (LC1-4) is more preferable. By using such a specific lactone structure, LER and development defects are improved.

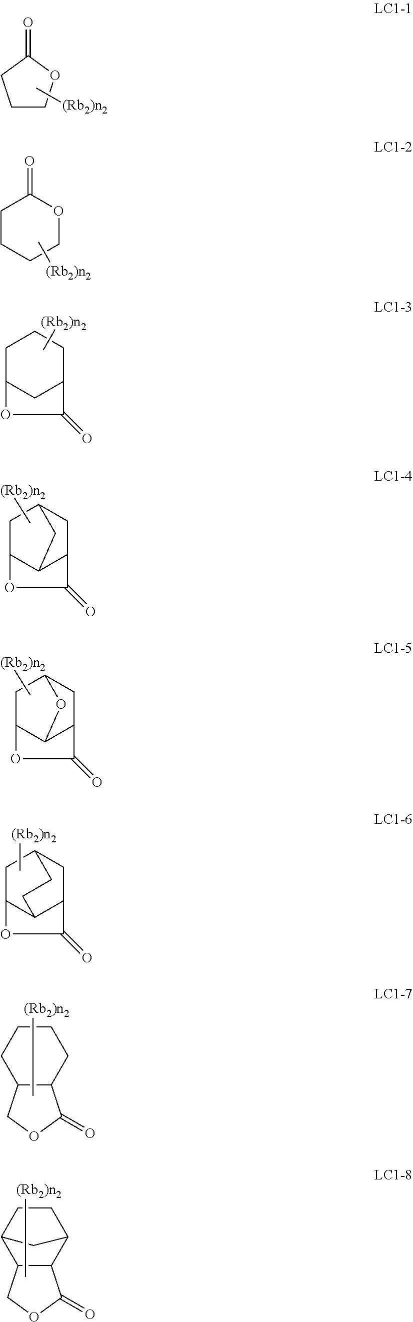

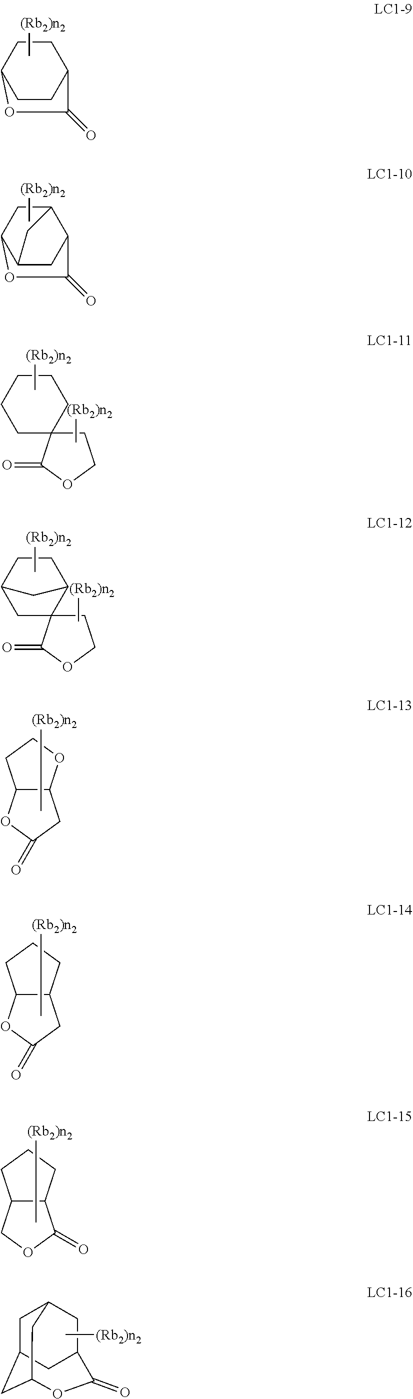

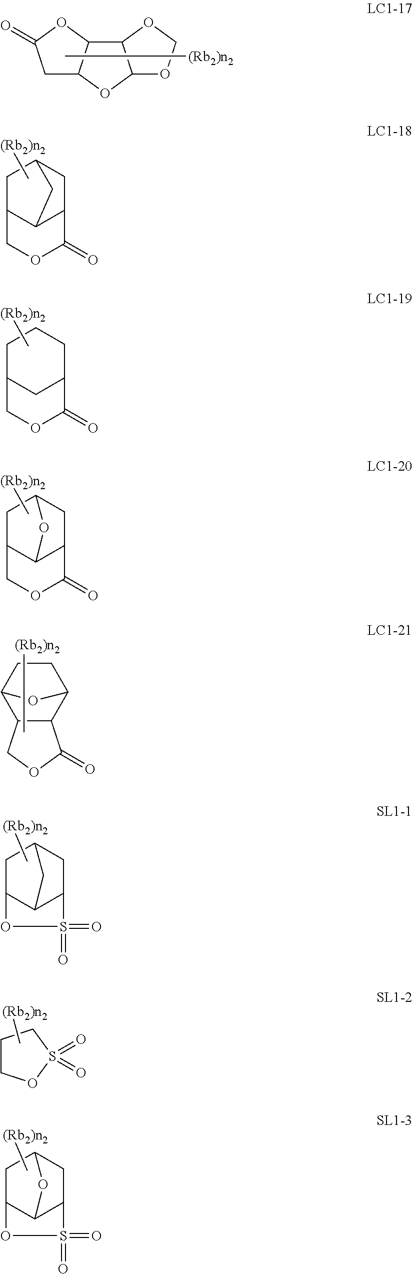

A lactone structural portion or a sultone structural portion may or may not have a substituent (Rb₂). Examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group, and an alkyl group having 1 to 4 carbon atoms, a cyano group, or an acid-decomposable group is preferable. n₂ represents an integer of 0 to 4. In a case where n₂ is 2 or more, a plurality of the substituents (Rb₂) may be the same as or different from each other. In addition, the plurality of the substituents (Rb₂) may be bonded to each other to form a ring.

In a case where the resin (A) contains a repeating unit having a lactone structure or a sultone structure, the content of the repeating unit having a lactone structure or a sultone structure is preferably 5 to 60 mol %, more preferably 5 to 55 mol %, and still more preferably 10 to 50 mol % with respect to all repeating units of the resin (A).

As the repeating unit having a carbonate structure (cyclic carbonate ester structure), a repeating unit represented by General Formula (A-1) is preferable.

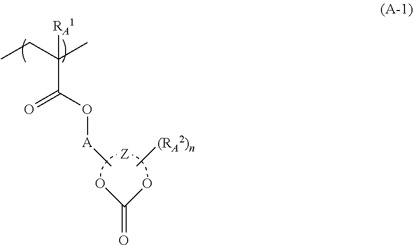

In General Formula (A-1), R_{A}¹ represents a hydrogen atom or an alkyl group.

In a case where n is 2 or more, R_{A}²'s each independently represent a substituent.

A represents a single bond or a divalent linking group.

Z represents an atomic group which forms a monocyclic or polycyclic structure together with a group represented by —O—C(═O)—O— in the formula. n represents an integer of 0 or more.

In the resin (A), the content of the repeating unit having a cyclic carbonate ester structure (preferably, the repeating unit represented by General Formula (A-1)) is preferably 3 to 80 mol %, more preferably 3 to 60 mol %, still more preferably 3 to 45 mol %, particularly preferably 3 to 30 mol %, and most preferably 10 to 15 mol % with respect to all repeating units constituting the resin (A). By setting such a content, it is possible to improve developability, low defect property, low line width roughness (LWR), low post exposure bake (PEB) temperature dependence, profile, and the like as the resist.

The resin (A) may have a repeating unit having a phenolic hydroxyl group.

Examples of the repeating unit having a phenolic hydroxyl group include a hydroxystyrene repeating unit and a hydroxystyrene (meth)acrylate repeating unit. Among these, the repeating unit having a phenolic hydroxyl group is preferably a repeating unit represented by General Formula (I).

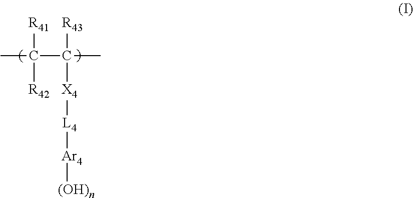

In the formula,

R₄₁, R₄₂, and R₄₃ each independently represent a hydrogen atom, an alkyl group, a cycloalkyl group, a halogen atom, a cyano group, or an alkoxycarbonyl group. However, R₄₂ may be bonded to Ar₄ to form a ring, and in this case, R₄₂ represents a single bond or an alkylene group.

X₄ represents a single bond, —COO—, or —CONR₆₄—, and R₆₄ represents a hydrogen atom or an alkyl group.

L₄ represents a single bond or a divalent linking group.

Ar₄ represents an (n+1)-valent aromatic hydrocarbon group, and in a case of being bonded to R₄₂ to form a ring, Ar₄ represents an (n+2)-valent aromatic hydrocarbon group.

n represents an integer of 1 to 5.

For the purpose of increasing polarity of the repeating unit represented by General Formula (I), it is also preferable that n is an integer of 2 or more, or X₄ is —COO— or —CONR₆₄—.

In the resin (A), with respect to all repeating units of the resin (A), the content of the repeating unit having a phenolic hydroxyl group is preferably 40 mol % or more, more preferably 50 mol % or more, and still more preferably 60 mol % or more, and is preferably 85 mol % or less and more preferably 80 mol % or less.

The resin (A) preferably has a repeating unit having a hydroxyl group or a cyano group, other than the above-described repeating units. As a result, adhesiveness to the substrate and affinity for a developer are improved. The repeating unit having a hydroxyl group or a cyano group is preferably a repeating unit having an alicyclic hydrocarbon structure substituted with a hydroxyl group or a cyano group, and it is preferable to not have an acid-decomposable group. In the alicyclic hydrocarbon structure substituted with a hydroxyl group or a cyano group, the alicyclic hydrocarbon structure is preferably an adamantyl group, a diamantyl group, or a norbornane group.

The content of the repeating unit having a hydroxyl group or a cyano group is preferably 5 to 40 mol %, more preferably 5 to 30 mol %, and still more preferably 10 to 25 mol % with respect to all the repeating units of the resin (A).

The resin (A) may have a repeating unit having an alkali-soluble group. Examples of the alkali-soluble group include a carboxyl group, a sulfonamide group, a sulfonylimide group, a bissulfonylimide group, and an aliphatic alcohol group (for example, a hexafluoroisopropanol group) in which the α-position is substituted with an electron withdrawing group, and it is preferable to have a repeating unit having a carboxyl group. In a case of containing the repeating unit having an alkali-soluble group, resolution for contact holes is increased. As the repeating unit having an alkali-soluble group, a repeating unit in which an alkali-soluble group is directly bonded to the main chain of a resin, such as a repeating unit with acrylic acid and methacrylic acid, or a repeating unit in which an alkali-soluble group is bonded to the main chain of the resin through a linking group is preferable. Further, it is also preferable to use any of a polymerization initiator or chain transfer agent having an alkali-soluble group to introduce the alkali-soluble group to an end of a polymer chain in a case of polymerization, and the linking group may have a monocyclic or polycyclic cyclic hydrocarbon structure. It is also preferable to use a repeating unit derived from (meth)acrylic acid.

The content of the repeating unit having an alkali-soluble group is preferably 0 to 20 mol %, more preferably 3 to 15 mol %, and still more preferably 5 to 10 mol % with respect to all repeating units of the resin (A).

The resin (A) of the present invention can further have a repeating unit which has an alicyclic hydrocarbon structure without a polar group (for example, the above-described alkali-soluble group, hydroxyl group, cyano group, and the like) and does not exhibit acid decomposition property. Examples of such the repeating unit include a repeating unit represented by General Formula (IV).

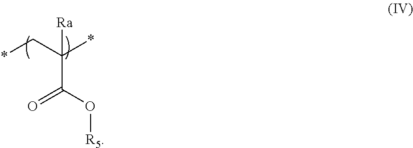

In General Formula (IV), R₅ represents a hydrocarbon group having at least one cyclic structure and having no polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and more preferably a hydrogen atom or a methyl group.

The cyclic structure included in R₅ includes a monocyclic hydrocarbon group and a polycyclic hydrocarbon group. Examples of the monocyclic hydrocarbon group include cycloalkyl groups having 3 to 12 carbon atoms, such as a cyclopentyl group, a cyclohexyl group, a cycloheptyl group, and a cyclooctyl group; and cycloalkenyl groups having 3 to 12 carbon atoms, such as a cyclohexenyl group. As the monocyclic hydrocarbon group, a monocyclic hydrocarbon group having 3 to 7 carbon atoms is preferable, and a cyclopentyl group or a cyclohexyl group is more preferable.

The resin (A) may or may not include the repeating unit which has an alicyclic hydrocarbon structure without a polar group and does not exhibit acid decomposition property. In a case where the resin (A) includes these repeating units, the content of the repeating units is preferably 1 to 40 mol % and more preferably 2 to 20 mol % with respect to all repeating units of the resin (A).

In a case where the resist composition is for ArF exposure, it is also preferable that the resin (A) does not substantially have an aromatic group from the viewpoint of transparency to ArF light. More specifically, the repeating unit having an aromatic group is preferably 5 mol % or less, more preferably 3 mol % or less, and still more preferably 0 mol % in all repeating units of the resin (A), that is, it is still more preferable that the repeating unit having an aromatic group is not included. In addition, the resin (A) preferably has a monocyclic or polycyclic alicyclic hydrocarbon structure.

It is also preferable that the resin (A) is a resin in which all repeating units are composed of (meth)acrylate-based repeating units. In this case, any resin of a resin in which all repeating units are methacrylate-based repeating units, a resin in which all repeating units are acrylate-based repeating units, or a resin with all repeating units consisting of a methacrylate-based repeating unit and an acrylate-based repeating unit can be used. Among these, a resin in which the acrylate-based repeating unit is 50 mol % or less of all repeating units is preferable.

The resin (A) can be synthesized in accordance with an ordinary method (for example, radical polymerization).

A weight-average molecular weight of the resin (A) is preferably 1,000 to 200,000, more preferably 2,000 to 40,000, still more preferably 3,000 to 30,000, and particularly preferably 4,000 to 25,000. By setting the weight-average molecular weight to 1,000 to 200,000, it is possible to prevent deterioration of heat resistance or dry etching resistance, and it is also possible to prevent deterioration of developability or deterioration in film-forming properties caused by an increase in a viscosity.

A dispersity (molecular weight distribution) of the resin (A) is usually 1.0 to 3.0, and preferably 1.0 to 2.6, more preferably 1.0 to 2.0, and still more preferably 1.1 to 2.0. As the molecular weight distribution is smaller, resolution and a resist shape are excellent, a side wall of the resist pattern is smoother, and roughness is excellent.

A content of the resin (A) is preferably 20% by mass or more, more preferably 40% by mass or more, still more preferably 60% by mass or more, and particularly preferably 80% by mass or more with respect to the total solid content of the resist composition. The content of the resin (A) is preferably 99% by mass or less with respect to the total solid content of the resist composition.

The resin (A) may be used alone or may be used in combination of two or more kinds thereof.

Photoacid Generator

The resist composition preferably includes a photoacid generator (compound which generates an acid by irradiation with actinic ray or radiation).

The photoacid generator is not particularly limited, but a compound which generates an organic acid by irradiation with actinic ray or radiation is preferable.

As the photoacid generator, a photoinitiator for photocationic polymerization, a photoinitiator for photoradical polymerization, a light-decoloring agent of coloring agents, a photochromic agent, or a known compound which generates an acid by irradiation with actinic ray or radiation and a mixture thereof, which are used for microresist or the like, can be appropriately selected and used, and examples thereof include compounds described in paragraphs 0039 to 0103 of JP2010-61043A and compounds described in paragraphs 0284 to 0389 of JP2013-4820A. However, the present invention is not limited thereto.

Examples thereof include a diazonium salt, a phosphonium salt, a sulfonium salt, an iodonium salt, imide sulfonate, oxime sulfonate, diazodisulfone, disulfone, and o-nitrobenzylsulfonate.

As the photoacid generator contained in the resist composition, for example, a compound (specific photoacid generator) generating an acid by irradiation with actinic ray or radiation, which is represented by Formula (3), is preferable.

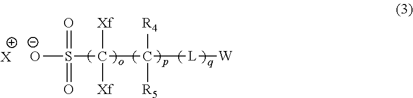

Anion

In Formula (3),

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where a plurality of R₄'s and R₅'s are present, the plurality thereof may be the same or different from each other.

L represents a divalent linking group, and in a case where a plurality of L's are present, the plurality thereof may be the same or different from each other.

W represents an organic group including a cyclic structure.

o represents an integer of 1 to 3. p represents an integer of 0 to 10. q represents an integer of 0 to 10.

Cation

In Formula (3), X⁺ represents a cation.

X⁺ is not particularly limited as long as it is a cation, but examples of a suitable aspect thereof include cations (portion other than Z⁻) in General Formulae (ZI), (ZII), and (ZIII) shown below.

Suitable Aspect

Examples of the suitable aspects of the specific photoacid generator include a compound represented by General Formula (ZI), (ZII), or (ZIII).

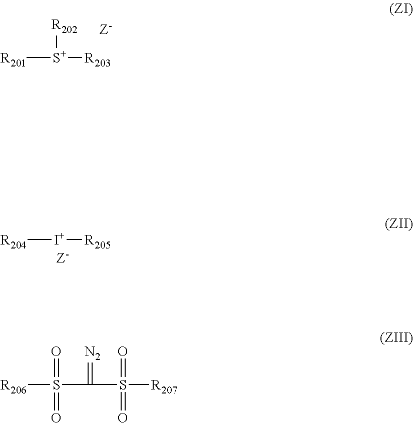

In General Formula (ZI),

R₂₀₁, R₂₀₂, and R₂₀₃ each independently represent an organic group.

The organic group as R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, and/or a carbonyl group. Examples of the group formed by the bonding of two of R₂₀₁ to R₂₀₃ include an alkylene group (for example, a butylene group and a pentylene group).

Z⁻ represents an anion, and the anion in Formula (3) described above is preferable.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The photoacid generator (including the specific photoacid generator; the same applies hereinafter) may be in a form of a low-molecular-weight compound, or may be in a form incorporated in a part of a polymer. In addition, a combination of the form of a low-molecular-weight compound and the form incorporated in a part of a polymer may also be used.

In a case where the photoacid generator is in the form of a low-molecular-weight compound, the molecular weight is preferably 580 or more, more preferably 600 or more, still more preferably 620 or more, and particularly preferably 640 or more. An upper limit thereof is not particularly limited, but is preferably 3000 or less, more preferably 2000 or less, and still more preferably 1000 or less.

In a case where the photoacid generator is incorporated in a part of a polymer, the photoacid generator may be incorporated in a part of the above-mentioned resin or in a resin other than the resin.

The photoacid generator can be synthesized by a known method, and can be, for example, synthesized according to a method described in JP2007-161707A.

The photoacid generator may be used singly or in combination of two or more kinds thereof. A content of the photoacid generator (in a case where a plurality of the photoacid generators are present, a total content thereof) in the composition is preferably 0.1% to 30% by mass, more preferably 0.5% to 25% by mass, still more preferably 3% to 20% by mass, and particularly preferably 3% to 15% by mass based on the total solid content of the composition.

In a case where the compound represented by General Formula (ZI-3) or (ZI-4) is included as the photoacid generator, the content of the photoacid generator (in a case where a plurality of the photoacid generators are present, a total content thereof) included in the composition is preferably 1.5% to 35% by mass, more preferably 5% to 35% by mass, still more preferably 9% to 30% by mass, and particularly preferably 9% to 25% by mass based on the total solid content of the composition.

Acid Diffusion Control Agent

The resist composition preferably contains an acid diffusion control agent. The acid diffusion control agent acts as a quencher which suppresses a reaction of an acid-decomposable resin in a non-exposed portion by excessive generated acids by trapping the acids generated from the photoacid generator and the like during exposure. As the acid diffusion control agent, a basic compound, a low-molecular-weight compound having a nitrogen atom and having a group eliminated due to the action of acid, a basic compound in which basicity decreases or disappears by irradiation with actinic rays or radiation, or an onium salt which is relatively a weak acid to the photoacid generator can be used.

Hydrophobic Resin

The resist composition may Include a hydrophobic resin other than the resin (A), in addition to the resin (A).

It is preferable that the hydrophobic resin is designed to be unevenly distributed on a surface of the resist film, but unlike a surfactant, the hydrophobic resin does not necessarily have a hydrophilic group in a molecule thereof and may not necessarily contribute to homogeneous mixing of polar substances and non-polar substances.

Examples of the effect of addition of the hydrophobic resin include a control of static and dynamic contact angles of a surface of the resist film with respect to water and suppression of out gas.

From the viewpoint of uneven distribution on the film surface layer, the hydrophobic resin preferably has any one or more of a “fluorine atom”, a “silicon atom”, or a “CH₃ partial structure which is included in a side chain moiety of a resin”, and more preferably has two or more kinds thereof. In addition, the above-described hydrophobic resin preferably has a hydrocarbon group having 5 or more carbon atoms. These groups may be included in the main chain of the resin or may be substituted in the side chain.

In a case where hydrophobic resin includes a fluorine atom and/or a silicon atom, the fluorine atom and/or the silicon atom in the hydrophobic resin may be included in the main chain or the side chain of the resin.

In a case where the resist composition includes a hydrophobic resin, a content of the hydrophobic resin is preferably 0.01% to 20% by mass, and more preferably 0.1% to 15% by mass with respect to the total solid content of the resist composition.

Solvent

It is preferable that the resist composition includes a solvent.

Examples of the solvent which can be used in preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include solvents described in paragraphs 0441 to 0455 of US2008/0187860A.

Surfactant

The resist composition may or may not further contain a surfactant.

The surfactant is preferably a fluorine-based and/or silicon-based surfactant (a fluorine-based surfactant, a silicon-based surfactant, or a surfactant having both a fluorine atom and a silicon atom).

The surfactants may be used singly or in combination of two or more kinds thereof.

In a case where the resist composition contains a surfactant, an amount of the surfactant used is preferably 0.0001% to 2% by mass, and more preferably 0.0005% to 1% by mass with respect to the total solid content of the resist composition.

Other Additives

The resist composition may or may not contain a carboxylic acid onium salt. Examples of such a carboxylic acid onium salt include those described in paragraphs 0605 and 0606 of US2008/0187860A.

These carboxylic acid onium salts can be synthesized by reacting a sulfonium hydroxide, an iodonium hydroxide, or an ammonium hydroxide with a carboxylic acid in a suitable solvent with silver oxide.

In a case where the resist composition contains a carboxylic acid onium salt, a content thereof is preferably 0.1% to 20% by mass, more preferably 0.5% to 10% by mass, and still more preferably 1% to 7% by mass with respect to the total solid content of the composition.

As necessary, the resist composition can further contain an acid proliferation agent, a dye, a plasticizer, a photosensitizer, a light absorbing agent, an alkali-soluble resin, a dissolution inhibitor, a compound which promotes solubility in a developer (for example, a phenol compound having a molecular weight of 1000 or less, and an alicyclic or aliphatic compound having a carboxyl group), or the like.

Such a phenol compound having a molecular weight of 1000 or less can be synthesized by those skilled in the art with reference to methods described in, for example, JP1992-122938A (JP-H4-122938A), JP1990-28531A (JP-H2-28531A), U.S. Pat. No. 4,916,210A, EP219294B, and the like.

Examples of the alicyclic or aliphatic compound having a carboxyl group include carboxylic acid derivatives having a steroid structure such as cholic acid, deoxycholic acid, and lithocholic acid, adamantanecarboxylic acid derivatives, adamantanedicarboxylic acid, cyclohexanecarboxylic acid, and cyclohexanedicarboxylic acid, but the present invention is not limited thereto.

A concentration of solid contents in the resist composition is preferably 1.0% to 20% by mass, more preferably 2.0% to 15% by mass, and still more preferably 2.0% to 10% by mass.

By setting the concentration of solid contents within the above-described range, a resist solution can be uniformly applied to the substrate, and further, it is possible to form a resist pattern having excellent line width roughness. The reason is not clear, but probably, it is considered that, by setting the concentration of solid contents to 20% by mass or less, aggregation of materials, particularly the photoacid generator, in the resist solution is suppressed, and as a result, a uniform resist film can be formed.

The concentration of solid contents in the resist composition means components of the resist composition, other than the solvent.

The concentration of solid contents in the resist composition is a weight percentage of weights of other resist components excluding the solvent with respect to the total weight of the composition.

A method for preparing the resist composition is not particularly limited, but it is preferable to dissolve each of the above-described components in a predetermined organic solvent, preferably in the above-described mixed solvent, and filter the composition. A filter used for the filtration using a filter is preferably made of polytetrafluoroethylene, polyethylene, or nylon, which has a pore size of 0.1 μm or less (preferably 0.05 μm or less and more preferably 0.03 μm or less). In the filtration using a filter, for example, circulating filtration may be performed or the filtration may be performed by connecting plural kinds of filters in series or in parallel, as described in JP2002-62667A. In addition, the composition may be filtered in plural times. Furthermore, the composition may be subjected to a deaeration treatment or the like before or after the filtration using a filter.

<Step R (Exposing Step)>

In the exposing step, the above-described resist film is exposed.

Light used in the exposure is not particularly limited, and examples thereof include infrared rays, visible light, ultraviolet rays, far ultraviolet rays, extreme ultraviolet rays, X-rays, and electron beams. A wavelength of the light is preferably 250 nm or less, more preferably 220 nm or less, and still more preferably 1 to 200 nm.

More specific examples thereof include a KrF excimer laser (248 nm), an ArF excimer laser (193 nm), an F₂ excimer laser (157 nm), X-rays, EUV (13 nm), and electron beams, and among these, a KrF excimer laser, an ArF excimer laser, EUV, or electron beams are preferable.

The exposure in the exposing step may be a liquid immersion exposure.

The liquid immersion exposure can be combined with super-resolution techniques such as a phase shift method and a modified illumination method. The liquid immersion exposure can be performed according to, for example, a method described in paragraphs 0594 to 0601 of JP2013-242397A.

After the step R (exposing step) and before the step S (developing step), the exposed resist film may be subjected to a heating treatment (Post Exposure Bake: PEB). This step promotes the reaction of the exposed portion. The heating treatment (PEB) may be performed in plural times.

A temperature in the heating treatment is preferably 70° C. to 130° C. and more preferably 80° C. to 120° C.

A time of the heating treatment is preferably 30 to 300 seconds, more preferably 30 to 180 seconds, and still more preferably 30 to 90 seconds.

The heating treatment can be performed using a unit included in an ordinary exposure machine and/or development machine, or may also be performed using a hot plate or the like.

<Step S (Developing Step)>

In the developing step, the exposed resist film is developed with a developer to form a resist pattern.

Examples of a preferred embodiment of the resist pattern include a resist pattern which has a line portion having a line width of 5000 nm or less. In the embodiment, the line width of the line portion is more preferably 1000 nm or less and still more preferably 500 nm or less. In addition, the line width of the line portion is usually 10 nm or more.

The developer in the developing step may be an alkali developer or a developer (organic developer) including an organic solvent.

As the alkali developer, a quaternary ammonium salt typified by tetramethylammonium hydroxide is usually used. In addition, an alkali aqueous solution including an inorganic alkali, primary to tertiary amines, alcohol amines, cyclic amines, and the like can also be used.

Specific examples of the alkali developer include alkaline aqueous solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; quaternary ammonium salts such as tetramethylammonium hydroxide and tetraethylammonium hydroxide; cyclic amines such as pyrrole and piperidine; and the like. Among these, it is preferable to use an aqueous solution of tetraethylammonium hydroxide.

Furthermore, alcohols or surfactants may be added to the above-described alkali developer in an appropriate amount. An alkali concentration of the alkali developer is usually 0.1% to 20% by mass. A pH of the alkali developer is usually 10.0 to 15.0. A time for performing the development using the alkali developer is usually 10 to 300 seconds.

The alkali concentration (and pH), and the development time of the alkali developer can be appropriately adjusted depending on a pattern formed.

After the development using the alkali developer, it may be washed with a rinsing liquid, and as the rinsing liquid, pure water may be used, and an appropriate amount of a surfactant may be added and used.

In addition, after the developing treatment or the rinsing treatment, a treatment of removing the developer or the rinsing liquid adhering to the pattern with a supercritical fluid can be performed.

Furthermore, after the rinsing treatment or the treatment using a supercritical fluid, a heating treatment for removing moisture remaining in the pattern can be performed.

As the organic developer include polar solvents such as a ketone-based solvent, an ester-based solvent, an alcohol-based solvent, an amide-based solvent, and an ether-based solvent, and hydrocarbon-based solvents can be used, and specific examples thereof include solvents described in paragraphs 0461 to 0463 of JP2014-048500A, methyl 2-hydroxyisobutyrate, butyl butyrate, isobutyl isobutyrate, butyl propionate, butyl butanoate, and isoamyl acetate.

A plurality of the above-described solvents may be mixed, or the solvent may also be used in admixture with a solvent other than those described above or water. However, a moisture content of the organic developer as a whole is preferably less than 10% by mass, and the organic developer is more preferably substantially free of the moisture.

That is, the content of the organic solvent to the organic developer is preferably 90% to 100% by mass and more preferably 95% to 100% by mass with respect to the total amount of the developer.

The organic developer is preferably a developer containing at least one organic solvent selected from the group consisting of a ketone-based solvent, an ester-based solvent, an alcohol-based solvent, an amide-based solvent, and an ether-based solvent.

A vapor pressure of the organic developer at 20° C. is preferably 5 kPa or less, more preferably 3 kPa or less, and still more preferably 2 kPa or less. By setting the vapor pressure of the organic developer to 5 kPa or less, evaporation of the developer on the substrate or in a development cup is suppressed, temperature uniformity in a wafer plane is improved, and as a result, dimensional uniformity in the wafer plane is improved.

An appropriate amount of a surfactant can be added to the organic developer, as necessary.

The surfactant is not particularly limited, but, for example, an ionic or nonionic fluorine-based and/or silicon-based surfactant, or the like can be used. Examples of the fluorine-based and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. Nos. 5,405,720A, 5,360,692A, 5,529,881A, 5,296,330A, 5,436,098A, 5,576,143A, 5,294,511A, and 5,824,451A. The surfactant is preferably nonionic surfactant. The nonionic surfactant is not particularly limited, but it is still more preferable to use a fluorine-based surfactant or a silicon-based surfactant.

An amount of the surfactant used is usually 0.001% to 5% by mass, preferably 0.005% to 2% by mass, and still more preferably 0.01% to 0.5% by mass with respect to the total amount of the developer.

The organic developer may include a basic compound. Specific examples and preferred examples of the basic compound which can be included in the organic developer used in the present invention include the same basic compounds which can be used as the acid diffusion control agent.

As a developing method, for example, a method in which the substrate is dipped in a tank filled with the developer for a certain period of time (a dipping method), a method in which development is performed by heaping the developer up onto a surface of the substrate by surface tension, and then stopping it for a certain period of time (a puddle method), a method in which the developer is sprayed on a surface of the substrate (a spray method), a method in which the developer is continuously jetted onto the substrate rotating at a constant rate while scanning a developer jetting nozzle at a constant rate (a dynamic dispensing method), or the like can be adopted.

A suitable range of a jetting pressure of the developer to be jetted, a method of adjusting the jetting pressure of the developer, and the like are not particularly limited, but for example, a range and method described in paragraphs 0631 to 0636 of JP2013-242397A.

In the pattern forming method according to the embodiment of the present invention, a combination of a step (alkali developing step) of performing development using the alkali developer and a step (organic solvent developing step) of performing development using a developer including an organic solvent may be used.

A portion with a low exposure intensity can be removed by the organic solvent developing step, and a portion with a high exposure intensity can be removed by performing the alkali developing step. By virtue of multiple development processes in which development is performed in plural times in such a manner, a pattern can be formed by keeping only a region with an intermediate exposure intensity from not being dissolved, so that a finer pattern than usual can be formed (the same mechanism as in paragraph 0077 of JP2008-292975A).

In this case, the order of the alkali developing step and the organic solvent developing step is not particularly limited, but it is more preferable that the alkali development is performed before the organic solvent developing step.

After the organic solvent developing step, it is preferable to include a washing step with a rinsing liquid.

The rinsing liquid used in the rinsing step after the organic solvent developing step is not particularly limited as long as the rinsing liquid does not dissolve the resist pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Water may be used as the rinsing liquid used in the rinsing step after the organic solvent developing step.

Specific examples of the hydrocarbon-based solvent, ketone-based solvent, ester-based solvent, alcohol-based solvent, amide-based solvent, and ether-based solvent include the same solvents as those described for the developer including an organic solvent.

After the organic solvent developing step, it is preferable to perform a washing step with a rinsing liquid containing at least one organic solvent selected from the group consisting of a ketone-based solvent, an ester-based solvent, an alcohol-based solvent, an amide-based solvent, and a hydrocarbon-based solvent, it is more preferable to perform a washing step with a rinsing liquid containing an alcohol-based solvent or an ester-based solvent, it is still more preferable to perform a washing step with a rinsing liquid containing a monohydric alcohol, and it is particularly preferable to perform a washing step with a rinsing liquid containing a monohydric alcohol having 5 or more carbon atoms.

As the rinsing liquid containing a hydrocarbon-based solvent, a hydrocarbon compound having 6 to 30 carbon atoms is preferable, a hydrocarbon compound having 8 to 30 carbon atoms is more preferable, and a hydrocarbon compound having 10 to 30 carbon atoms is particularly preferable. Among these, by using a rinsing liquid containing decane and/or undecane, pattern collapse is suppressed.

In a case where the ester-based solvent is used as the organic solvent, a glycol ether-based solvent may be used in addition to the ester-based solvent (one type or two or more types). Specific examples in this case include a case in which an ester-based solvent (preferably, butyl acetate) is used as a main component, and a glycol ether-based solvent (preferably, propylene glycol monomethyl ether (PGME)) is used as a sub-component. As a result, residual defects are further suppressed.

Here, examples of the monohydric alcohol used in the rinsing step include linear, branched, or cyclic monohydric alcohols, and examples thereof include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, and 4-octanol.

A plurality of the respective components may be mixed with, or the components may also be used in admixture with an organic solvent other than the solvents.

A moisture content in the rinsing liquid is preferably 10% by mass or less, more preferably 5% by mass or less, and still more preferably 3% by mass or less. By setting the moisture content to 10% by mass or less, good development characteristics can be obtained.

A vapor pressure of the rinsing liquid used after the step of performing development using a developer including an organic solvent at 20° C. is preferably 0.05 to 5 kPa, more preferably 0.1 to 5 kPa, and still more preferably 0.12 to 3 kPa. By setting the vapor pressure of the rinsing liquid within the above-described range, the temperature uniformity in the wafer plane is enhanced, swelling due to the permeation of the rinsing liquid is suppressed, and the dimensional uniformity in the wafer plane is improved.

An appropriate amount of a surfactant may be added to the rinsing liquid before use.

In the rinsing step, the developed substrate (resist pattern on the substrate) is washed with the above-described rinsing liquid. A method for the washing treatment is not particularly limited, for example, a method in which a rinsing liquid is continuously jetted on a substrate rotating at a constant rate (a spin coating method), a method in which a substrate is dipped in a tank filled with a rinsing liquid for a certain period of time (a dipping method), a method in which a rinsing liquid is sprayed on a substrate surface (a spray method), and/or the like, and among these, a method in which a washing treatment is performed using the rotation application method, and a substrate is rotated at a rotation speed of 2000 to 4000 rpm after washing, thereby removing the rinsing liquid from the substrate, is preferable. Furthermore, it is also preferable that the method includes a heating step (post bake) after the rinsing step. The developer and the rinsing liquid remaining between and inside the patterns are removed by the baking. The heating step after the rinsing step is performed, usually at 40° C. to 160° C. (preferably 70° C. to 95° C.), and usually for 10 seconds to 3 minutes (preferably for 30 seconds to 90 seconds).

It is preferable that the various materials (for example, the developer, the rinsing liquid, and the like) used in the pattern forming method according to the embodiment of the present invention do not include impurities such as metals. Examples of the metal impurity component include Na, K, Ca, Fe, Cu, Mn, Mg, Al, Cr, Ni, Zn, Ag, Sn, Pb, and Li. A total content of the impurities included in these materials is preferably 1 part per million (ppm) by mass or less, more preferably 10 ppb by mass or less, still more preferably 100 parts per trillion (ppt) by mass or less, particularly preferably 10 ppt by mass or less, and most preferably 1 ppt by mass or less.

Examples of a method for removing the impurities such as metals from the above-described various materials include filtration using a filter. As a filter pore diameter, a pore size is preferably 50 nm or less, more preferably 10 nm or less, and still more preferably 5 nm or less. As a material of the filter, a polytetrafluoroethylene-made, polyethylene-made, or nylon-made filter is preferable. In the step of filtration using a filter, a plurality of kinds of filters may be connected and used in series or in parallel. In a case of using the plurality of kinds of filters, a combination of filters having different pore diameters and/or materials may be used. In addition, various materials may be filtered plural times, and the step of filtering plural times may be a circulatory filtration step.

In addition, examples of a method for reducing the impurities such as metals included in the above-described various materials include a method of selecting a raw material having a low metal content as a raw material constituting the various materials, performing filtration using a filter on the raw material constituting the various materials, and the like. Preferred conditions for the filtration using a filter performed on the raw materials constituting the various materials are the same ones as the above-described conditions.

In addition to the filtration using a filter, the impurities may be removed by an adsorbing material, or the filtration and the adsorbing material may be used in combination. As the adsorbing material, a known adsorbing material can be used, and for example, inorganic adsorbing materials such as silica gel and zeolite, and organic adsorbing materials such as activated carbon can be used.

It is necessary to prevent the incorporation of metal impurities in the production process in order to reduce the impurities such as metals included in the various materials. Sufficient removal of the metal impurities from a production device can be confirmed by measuring the content of metal components included in a washing solution used to wash the production device. The content of the metal components included in the washing solution after the use is preferably 100 parts per trillion (ppt) by mass or less, more preferably 10 ppt by mass or less, and still more preferably 1 ppt by mass or less.

A conductive compound may be added to an organic treatment liquid (resist solvent, developer, rinsing liquid, and the like) used in the resist pattern forming method according to the embodiment of the present invention in order to prevent breakdown of chemical liquid pipes and various parts (a filter, an O-ring, a tube, or the like) due to electrostatic charging, and subsequently generated electrostatic discharging. The conductive compound is not particularly limited, but examples thereof include methanol. The addition amount is not particularly limited, but from the viewpoint of maintaining good development characteristics, the addition amount is preferably 10% by mass or less and more preferably 5% by mass or less. With regard to the members of the chemical liquid pipe, it is possible to use various pipes coated with stainless steel (SUS), or a polyethylene resin, a polypropylene resin, or a fluororesin (a polytetrafluoroethylene resin, a perfluoroalkoxy resin, or the like), which has been subjected to an antistatic treatment. Similarly, a polyethylene resin, a polypropylene resin, or a fluororesin (a polytetrafluoroethylene resin, a perfluoroalkoxy resin, or the like), which has been subjected to an antistatic treatment, can be used for a filter and an O-ring.

A method for improving the surface roughness of a pattern may be adopted to the resist pattern formed by the method of the embodiment of the present invention. Examples of the method for improving the surface roughness of the pattern include the method of treating a resist pattern by a plasma of a hydrogen-containing gas described in WO2014/002808A. In addition, known methods as described in JP2004-235468A, US2010/0020297A, JP2008-83384A, and Proc. of SPIE Vol. 8328 83280N-1 “EUV Resist Curing Technique for LWR Reduction and Etch Selectivity Enhancement” may be adopted.

The resist pattern forming method according to the embodiment of the present invention can also be used for forming a guide pattern in a directed self-assembly (DSA) (see, for example, ACS Nano Vol. 4, No. 8, Pages 4815-4823).

In addition, the resist pattern formed by the method can be used as a core material (core) of the spacer process disclosed in, for example, JP1991-270227A (JP-H3-270227A) and JP2013-164509A.

In addition, a resist pattern miniaturization process may be adopted to the resist pattern formed by the method of the present invention. Examples of the resist pattern miniaturization process include a method of applying a miniaturization composition on the pattern and heating it to increase the width of the resist pattern, as shown in JP2013-145290A and JP2014-071424A. In order to maintain etching resistance of the resist pattern after the miniaturization process, it is preferable that the miniaturization composition contains a silicon atom.

<Other Steps>

Using the resist pattern obtained by the above-described method as a mask, a step of processing (etching such as dry etching) the underlayer film and/or the second underlayer film to form an underlayer pattern and/or a second underlayer pattern may be performed. Thereafter, a step of further processing (etching such as dry etching) the substrate to form a pattern on the substrate may be performed.

A method for processing the underlayer film and/or the second underlayer film is not particularly limited.

Among these, as the process of the underlayer film and/or the second underlayer film, a treatment of forming the underlayer pattern and/or the second underlayer pattern by etching (dry etching or the like) on the underlayer film and/or the second underlayer film using the resist pattern as a mask is preferable.

In addition, in a case of etching the underlayer film, the second underlayer pattern may be used as the mask.

The dry etching may be one-stage etching or multi-stage etching. In a case where the etching is an etching including a plurality of stages, the etchings at the respective stages may be the same treatment or different treatment.

A system of a dry etching device is not particularly limited, but in particular, a system in which a plasma density and a bias voltage are independently controlled, such as an inductive coupled plasma (ICP; inductive coupling) type, a dual frequency conducive coupled plasma (CCP; capacitive coupling) type, and an electron cyclotron resonance (ECR) type, is more preferable.

For the etching, any known methods can be used, and various conditions and the like are appropriately determined according to the type of the substrate, usage, and the like. The etching can be carried out, for example, in accordance with The International Society for Optical Engineering (Proc. of SPIE), Vol. 6924, 692420 (2008), JP2009-267112A, and the like. In addition, the etching can also be carried out in accordance with “Chapter 4 Etching” in “Semiconductor Process Text Book, 4th Ed., published in 2007, publisher: SEMI Japan”.

An etching gas used for the dry etching of the second underlayer film can be appropriately selected depending on the element composition of the underlayer film to be etched, and the like, and examples thereof include fluorine gas such as CHF₃, CF₄, C₂F₆, C₃F₈, and SF₆; chlorine gas such as Cl₂ and BCl₃; oxygen gas such as O₂, O₃, and H₂O; gas such as H₂, NH₃, CO, and CO₂; and inert gas such as He, N₂, and Ar. One type or two or more types of these gases can be used.

As the etching gas used for etching the second underlayer film, a fluorine gas is preferable, and an etching gas obtained by mixing an oxygen gas and inert gas with the fluorine gas is preferable.

In addition, in a case of forming the second underlayer film, it is preferable to performing etching (dry etching or the like) of the underlayer film which is an organic layer using the second underlayer pattern as a mask, and then performing etching of the substrate. In this case, it is also preferable to use the underlayer pattern obtained by etching the underlayer film as a mask for etching the substrate.

As the etching used for the dry etching of the underlayer film, an oxygen plasma etching is preferable.

The oxygen plasma etching here means a plasma etching using a gas containing an oxygen atom, and specifically, at least one selected from the group consisting of O₂, O₃, CO, CO₂, NO, NO₂, N₂O, SO, SO₂, and COS is selected. Further, in addition to the above-described oxygen-containing gas, at least one selected from the group consisting of Ar, He, Xe, Kr, and N₂ may be added as a diluting gas, and at least one selected from the group consisting of Cl₂, HBr, BCl₃, CH₄, and NH₄ may be further added as an additive gas.

To suppress pattern dimensional fluctuations before and after the etching, by increasing a proportion of oxygen atom and oxygen-containing gas including at least one of C, N, S, or the like (for example, CO, CO₂, NO, NO₂, N₂O, SO, SO₂, and/or COS), a sedimentary component generated in the plasma adheres to a side wall of the etching processing pattern, suppresses the side etching effect due to oxygen radicals, and makes it possible to reduce the line width narrowing before and after the etching. The above-described effects are similarly exhibited by adding CH₄ or NH₄ as an additive gas to the oxygen-containing gas (for example, O₂, O₃, CO, CO₂, NO, NO₂, N₂O, SO, SO₂, and/or COS).

In addition, by using a gas containing a halogen element other than fluorine, such as Cl₂ and Hbr, high boiling point carbon chlorides and carbon bromides are formed as etching products of the underlayer film, and adhesion to the side wall of the processing pattern is enhanced. Even in this case, the effect of suppressing side etching by oxygen radicals can be expected.

On the other hand, by appropriately selecting a mixing ratio of O₂ or O₃ gas and the diluting gas, it is also possible to control the amount of side etching of the resist film (resist pattern) and the underlayer film, and to perform trimming processing of a desired dimensional amount at the same time as the etching.

The processing of the substrate is preferably a treatment of forming a pattern by etching (dry etching or the like) on the substrate using the underlayer pattern and/or the second underlayer pattern formed as described above as a mask.

As the etching gas used for etching the substrate, an oxygen gas is preferable, and an etching gas obtained by mixing an inert gas with the oxygen gas is more preferable.

In the semiconductor device manufacturing, in a case where the pattern formation is performed on the substrate as described above, a step of inspecting whether the target pattern dimension is actually formed after the pattern formation may be performed. In a case where the size is out of the allowable range, a method of removing the underlayer film, the second underlayer film, and/or the resist pattern, and then re-forming the pattern from the formation of the underlayer film, the second underlayer film, and/or the resist film is generally performed (rework step).

In this case, it is important to completely remove the underlayer film, the second underlayer film, and/or the resist film on the substrate in order to prevent occurrence of defects in the exposing step, the developing step, and the like. In a resist film peeling method, by a dry treatment (ashing) using oxygen gas, it is possible to almost completely peel off the resist film by removing most of the organic compounds on the substrate and then rinsing as necessary, which is widely performed.

In addition to the dry treatment as described above, a wet treatment may be performed in the rework step. Examples of a treatment liquid (stripper) applied in this case include a mixed liquid of sulfuric acid and hydrogen peroxide water, a dilute fluorine aqueous solution, an alkali aqueous solution, and an organic solvent, but the present invention is not limited thereto.

In the above-described wet treatment, it is more preferable to add a surfactant to the treatment liquid in order to effectively perform wet peeling. Examples of the surfactant include a fluorine-based surfactant and a silicon-based surfactant.

Before the wet peeling step, it is also possible to adopt a process such as full exposure and/or heating to the substrate on which the resist film is formed. By accelerating polarity conversion reaction of the resist film, the effect of improving solubility in the wet treatment liquid can be expected.

The present invention also relates to an ion implantation method in which ions are implanted into a substrate using the pattern obtained by the above-described pattern formation as a mask.

As the ion implantation method, any known method can be adopted.

In addition, the present invention also relates to a kit including a composition for forming an underlayer film and a resist composition, which is used in the pattern forming method according to the embodiment of the present invention described above.

[Manufacturing Method of Electronic Device]

In addition, the present invention also relates to a manufacturing method of an electronic device, which includes the resist pattern forming method according to the embodiment of the present invention described above or an ion implantation method.

The electronic device manufactured by the manufacturing method of an electronic device according to the embodiment of the present invention can be suitably mounted on electric or electronic apparatus (home electronics, office automation (OA), media-related equipment, optical equipment, and telecommunication equipment).

### EXAMPLES

Hereinbelow, the present invention will be described in more detail with reference to Examples. The materials, the amounts and proportions of the materials used, the details of treatments, the procedure of treatments, and the like shown in the following Examples can be appropriately modified as long as the gist of the present invention is maintained. Accordingly, the scope of the present invention will not be restrictively interpreted by the following Examples.

[Production of Composition for Forming Underlayer Film]

Components included in compositions for forming an underlayer film, used in Examples or Comparative Examples, and a manufacturing procedure are shown below.

<Polymer Containing Aromatic Ring>

### (Synthesis Example 1 (Synthesis of Compound (A-1))

Into a three-neck flask equipped with a condenser, 100 g of 2,7-dihydroxynaphthalene, 100 g of propylene glycol monomethyl ether acetate, 2 g of oxalic acid, and 50 g of paraformaldehyde were charged. The contents of the flask were reacted at 100° C. for 24 hours to obtain a polymer (Mw=1400) having the following structure. The polymer is referred to as a compound (A-1).

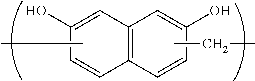

### (Synthesis Example 2 (Synthesis of Compound (A-2))

Into a three-neck flask equipped with a condenser, 50 g of 6,6′-(9H-fluoren-9,9-diyl)di(2-naphthol), 50 g of paraformaldehyde, 5 g of oxalic acid, and 50 g of dioxane were charged. The contents of the flask were reacted at 100° C. for 24 hours to obtain a polymer (Mw=4000) having the following structure. The polymer is referred to as a compound (A-2).

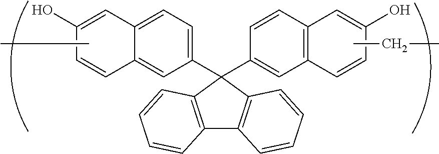

### Other Synthetic Examples

Compounds (A-3) to (A-5), and (A-7) were synthesized with reference to the above-described synthesis example.

A compound (A-6) was synthesized using a known method.

Structures and weight-average molecular weights (Mw) of the compounds (A-1) to (A-7) are shown below.

The description of the ratio attached to each repeating unit means a molar ratio of the content of each repeating unit in each compound.

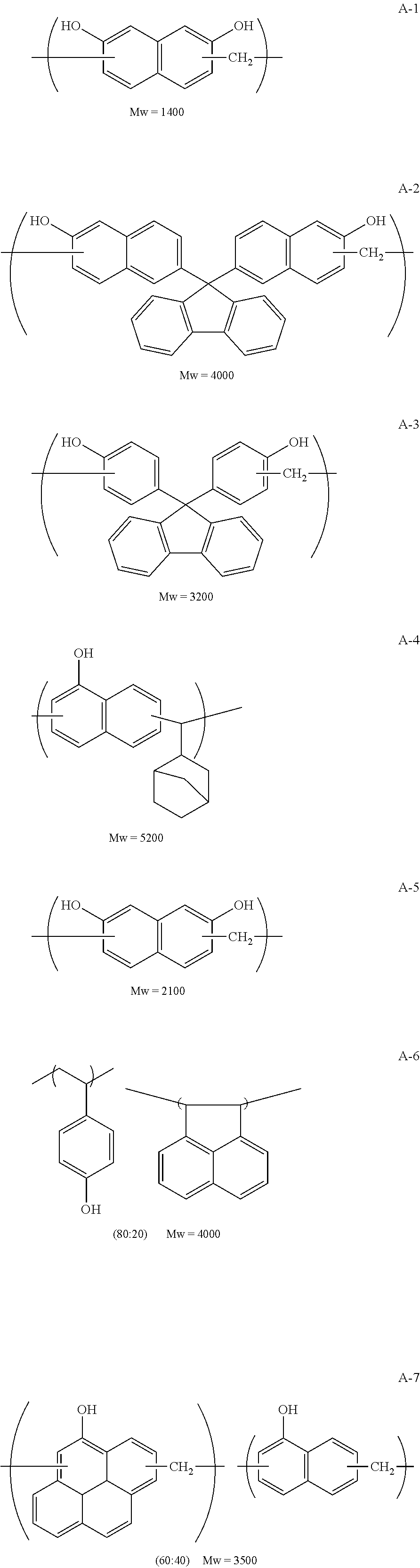

<Crosslinking Agent>

The following compounds were used as a crosslinking agent.

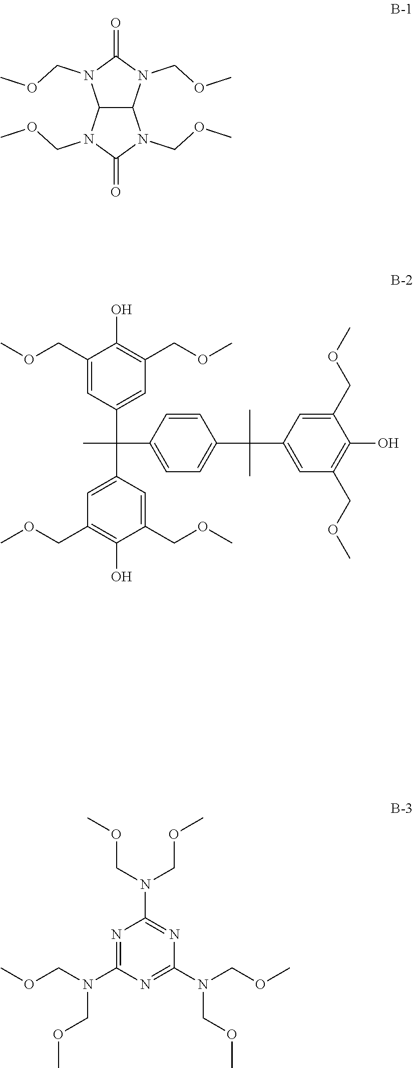

<Acid Generator>

The following compounds were used as an acid generator.

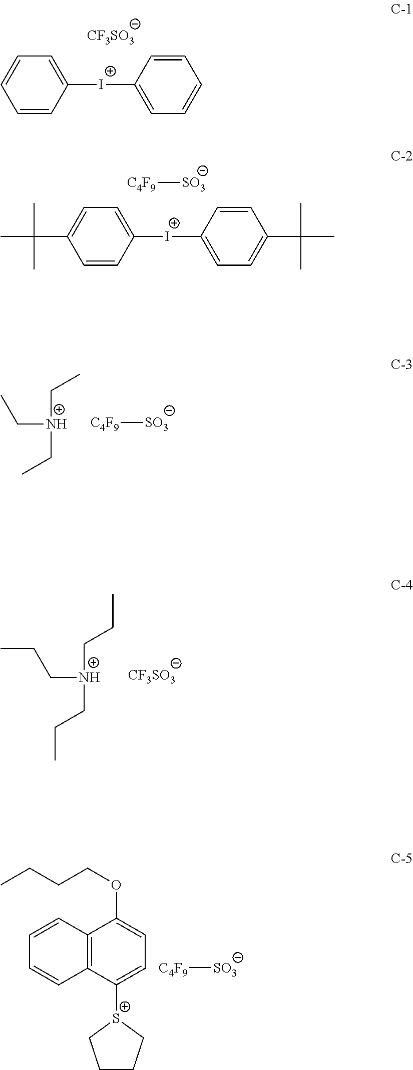

<Halogen-Based Organic Solvent>

The following compounds were used as a halogen-based organic solvent.
D-1: methylene chloride
D-2: chloroform
D-3: trichloroethylene
D-4: o-dichlorobenzene
D-5: benzotrifluoride

<Solvent>

The following compounds were used as a solvent (non-halogen-based solvent).
SL-1: propylene glycol monomethyl ether acetate
SL-2: cyclohexanone
SL-3: propylene glycol monomethyl ether

<Preparation of Composition for Forming Underlayer Film>

After mixing each component with the composition shown in the table shown in the latter part, composition for forming an underlayer film of each Example or Comparative Example was prepared by filtration through a polyethylene filter having a pore size of 0.03 μm. For the components other than the halogen-based organic solvent, amounts (parts by mass) shown in the table were mixed. The halogen-based organic solvent was mixed by adjusting an addition amount so that the content of the halogen-based organic solvent with respect to the total mass of the composition for forming an underlayer film was the amount (ppm by mass) shown in the table.

[Test]

<Formation of Underlayer Film>

The composition for forming an underlayer film of each Example or Comparative Example was applied to a silicon wafer substrate by a spin coating method. Thereafter, the substrate was heated at 250° C. for 60 seconds under an air atmosphere to form an underlayer film having an average thickness of 200 nm.

<Solvent Resistance>

The obtained substrate with the underlayer film was immersed in cyclohexanone at 25° C. for 5 minutes, and changes in average film thickness of the underlayer film before and after the immersion were compared.

In a case where an average film thickness before the immersion was defined as XO and an average film thickness after the immersion was defined as X, the absolute value of the numerical value obtained by (X−X0)×100/X0 was calculated, and the absolute value was regarded as a rate (%) of change in film thickness.

Solvent resistance was evaluated as “A” (very good) in a case where the rate of change in film thickness was less than 1%, “B” (good) in a case of being 1% or more and less than 3%, “C” (slightly good) in a case of being 3% or more and less than 5%, and “D” (poor) in a case of being 5% or more.

<Surface Flatness (Flatness)>

The composition for forming an underlayer film of each Example or Comparative Example was applied to a 12-inch diameter SiO₂ stepped substrate in which a trench (aspect ratio: 4.3) having a width of 42 nm, a pitch of 84 nm, and a depth of 180 nm and a trench (aspect ratio: 1.8) having a width of 100 nm, a pitch of 150 nm, and a depth of 180 nm were present.

Thereafter, the substrate was heated at 250° C. for 60 seconds under an air atmosphere to form an underlayer film having a film thickness of 200 nm. The film thickness of the underlayer film herein is intended to be an average distance, using a height of a recess portion of the stepped substrate (bottom of the trench) as a reference height, from the reference height to a surface of the underlayer film.

The shape of the underlayer film was observed with a scanning electron microscope (“S-4800” of Hitachi High-Technologies Corporation), and a difference (AFT) between the maximum value and the minimum value of the film thickness of the underlayer film was measured. Surface flatness was evaluated as “A” (very good) in a case where the AFT was less than 5 nm, “B” (good) in a case of being 5 nm or more and less than 10 nm, “C” (slightly good) in a case of being 10 nm or more and less than 20 nm, and “D” (poor) in a case of being 20 nm or more.

[Result]

The table below shows compositions and test results of the composition for forming an underlayer film of each Example or Comparative Example.

Each composition for forming an underlayer film includes the “Polymer containing aromatic ring”, “Crosslinking agent”, “Acid generator”, and “Solvent” in parts by mass as shown in the table, and includes the halogen-based organic solvent in the content (ppm by mass) as shown in the table with respect to the total mass of the composition for forming an underlayer film.

Values in parentheses in the column of “Solvent” indicate a mixing ratio (mass ratio) of solvents in a case where two or more kinds of the solvents were used.

In the table, the column of “Ratio X” indicates the content (ppm by mass) of the halogen-based organic solvent in each composition for forming an underlayer film with respect to the content of the novolac resin. In a case where the composition for forming an underlayer film did not contain the novolac resin, it is described as “-”.

TABLE 1

| | Composition for forming underlayer film | | | | | | | | | | | | |
|---|---|---|---|---|---|---|---|---|---|---|---|---|---|
| | Polymer | | | | | | | | | | | | |
| | containing | | Crosslinking | | | | Halogen-based | | | | | | |
| | aromatic ring | | agent | | Acid generator | | organic solvent | | Solvent | | Ratio X | Result | |
| | | Part by | | Part by | | Part by | | Ppm by | | Part by | (ppm by | | Solvent |
| | Type | mass | Type | mass | Type | mass | Type | mass | Type | mass | mass) | Flatness | resistance |
| Example 1 | A-1 | 90 | B-1 | 10 | C-2 | 5 | D-1 | 0.9 | SL-1 | 500 | 6.1 | A | A |
| Example 2 | A-1 | 90 | B-2 | 10 | | | D-2 | 0.005 | SL-1/SL-2 | 500 | 0.03 | C | A |
| | | | | | | | | | (8/2) | | | | |
| Example 3 | A-1 | 90 | B-1 | 10 | C-2 | 5 | D-1 | 20 | SL-1 | 500 | 134 | A | C |
| Example 4 | A-2 | 90 | B-1 | 10 | C-3 | 5 | D-1 | 0.2 | SL-1 | 500 | 1.3 | A | A |
| Example 5 | A-2 | 90 | B-1 | 10 | C-4 | 5 | D-1 | 0.008 | SL-1 | 500 | 0.05 | C | A |
| Example 6 | A-2 | 90 | B-1 | 10 | C-3 | 5 | D-1 | 1 | SL-1 | 500 | 6.7 | A | A |
| Example 7 | A-3 | 90 | B-2 | 10 | C-1 | 5 | D-1 | 0.8 | SL-1 | 500 | 5.4 | A | A |
| Example 8 | A-3 | 90 | B-1 | 10 | C-5 | 5 | D-3 | 42 | SL-1 | 500 | 282 | A | C |
| Example 9 | A-4 | 90 | B-1 | 10 | | 5 | D-1 | 0.011 | SL-1/SL-3 | 500 | 0.07 | A | B |
| | | | | | | | | | (8/2) | | | | |
| Example 10 | A-4 | 90 | B-3 | 10 | C-5 | 5 | D-4 | 0.2 | SL-1 | 500 | 1.3 | A | A |
| Example 11 | A-5 | 90 | B-1 | 10 | | 5 | D-2 | 0.08 | SL-1 | 500 | 0.54 | A | A |
| Example 12 | A-5 | 90 | B-1 | 10 | C-4 | 5 | D-1 | 33 | SL-2 | 500 | 222 | A | C |
| Example 13 | A-6 | 90 | B-1 | 10 | C-2 | 5 | D-1 | 2 | SL-1 | 500 | — | B | A |
| Example 14 | A-6 | 90 | B-1 | 10 | C-1 | 5 | D-5 | 45 | SL-1 | 500 | — | A | C |
| Example 15 | A-7 | 90 | B-1 | 10 | C-2 | 5 | D-1 | 3 | SL-1 | 500 | 20 | B | A |
| Example 16 | A-7 | 90 | B-1 | 10 | C-3 | 5 | D-1 | 13 | SL-1/SL-2 | 500 | 87 | A | C |
| | | | | | | | | | (8/2) | | | | |
| Example 17 | A-1 | 85 | B-1 | 15 | C-3 | 5 | D-1 | 0.022 | SL-1 | 500 | 0.16 | A | A |
| Example 18 | A-1 | 95 | B-1 | 8 | C-1 | 2 | D-2 | 0.003 | SL-1 | 500 | 0.02 | C | A |
| Example 19 | A-2 | 80 | B-1 | 20 | C-3 | 5 | D-1 | 7 | SL-1 | 500 | 53 | B | A |
| Example 20 | A-2 | 85 | B-1 | 10 | C-4 | 10 | D-1 | 0.9 | SL-2 | 500 | 6.4 | A | A |
| Example 21 | A-3 | 70 | B-1 | 30 | C-3 | 5 | D-1 | 0.006 | SL-1 | 500 | 0.05 | C | A |
| Example 22 | A-3 | 85 | B-1 | 10 | C-2 | 10 | D-2 | 0.9 | SL-2 | 500 | 6.4 | A | A |
| Comparative | A-1 | 90 | B-1 | 10 | C-1 | 5 | | 0 | SL-1 | 500 | 0 | D | A |
| Example 1 | | | | | | | | | | | | | |
| Comparative | A-2 | 90 | B-1 | 10 | C-1 | 5 | D-1 | 65 | SL-1 | 500 | 437 | A | D |
| Example 2 | | | | | | | | | | | | | |

From the results shown in the table, it was confirmed that the composition for forming an underlayer film according to the embodiment of the present invention can be used to form an underlayer film having excellent surface flatness and solvent resistance.

Among these, in a case where the content of the halogen-based organic solvent was 0.01 to 10 ppm by mass with respect to the total mass of the composition for forming an underlayer film, it was confirmed that the effects of the present were more excellent (comparison between Examples satisfying this requirement and Examples not satisfying this requirement).

In a case where the content of the halogen-based organic solvent was 0.1 to 10 ppm by mass with respect to the content of the novolac resin, it was confirmed that the effects of the present were more excellent (results of Examples 1, 4, 6, 7, 10, 11, 17, 20, 22, and the like).

What is claimed is:

1. A composition for forming an underlayer film, which is used for forming an underlayer film under a resist film, the composition comprising:
a monomer or a polymer containing an aromatic ring; and
a halogen-based organic solvent including 1 or more carbon atoms,
wherein a content of the halogen-based organic solvent is 0.001 to 50 ppm by mass with respect to a total mass of the composition for forming an underlayer film.

2. The composition for forming an underlayer film according to claim 1,
wherein the content of the halogen-based organic solvent is 0.01 to 10 ppm by mass with respect to the total mass of the composition for forming an underlayer film.

3. The composition for forming an underlayer film according to claim 1, further comprising:
a crosslinking agent.

4. The composition for forming an underlayer film according to claim 1, further comprising:
an acid generator.

5. The composition for forming an underlayer film according to claim 4,
wherein the acid generator is a compound represented by any one of General Formula (1), (2), or (3), 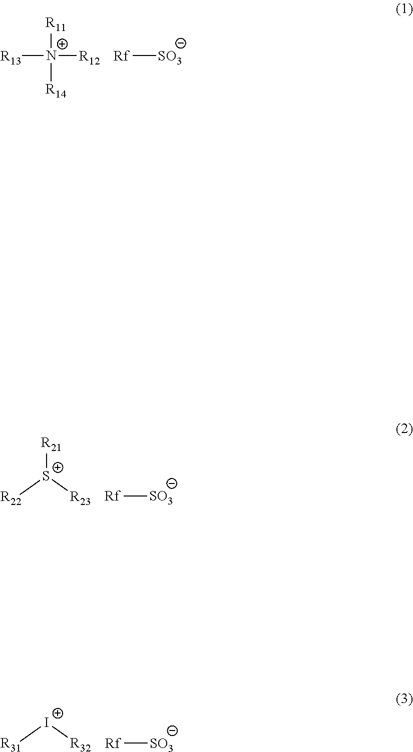
in General Formulae (1) to (3), R₁₁ to R₁₄, R₂₁ to R₂₃, R₃₁, and R₃₂ each independently represent a hydrogen atom, an alkyl group, or an aryl group, and Rf represents an organic group having one or more fluorine atoms,
in General Formula (2), two of R₂₁ to R₂₃ may be bonded to each other to form a ring.

6. The composition for forming an underlayer film according to claim 1,
wherein the halogen-based organic solvent includes one or more kinds selected from the group consisting of methylene chloride, chloroform, trichloroethylene, o-dichlorobenzene, and benzotrifluoride.

7. The composition for forming an underlayer film according to claim 1,
wherein the composition for forming an underlayer film includes the polymer containing an aromatic ring, and
the polymer containing an aromatic ring is a novolac resin having one or more repeating units represented by any of General Formula (A01), . . . , or (A06), 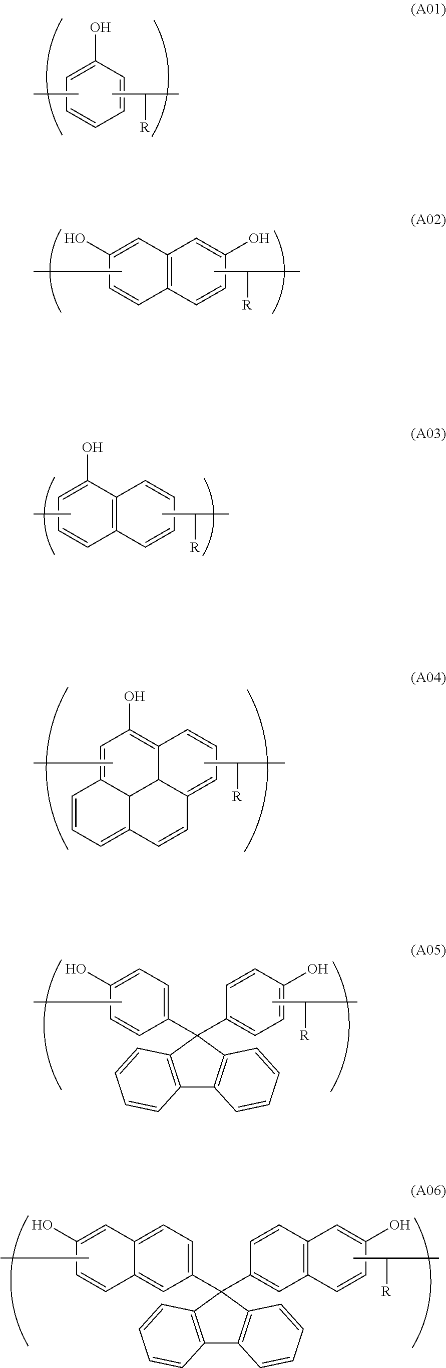
in General Formulae (A01) to (A06), R represents a hydrogen atom, an alkyl group, an alkenyl group, an alicyclic group, or an aryl group.

8. The composition for forming an underlayer film according to claim 7,
wherein the content of the halogen-based organic solvent is 0.1 to 10 ppm by mass with respect to a content of the novolac resin.

9. A resist pattern forming method comprising:
a step of forming an underlayer film on a substrate by using the composition for forming an underlayer film according to claim 1;
a step of forming a second underlayer film on the underlayer film by using a composition for forming a second underlayer film, which includes a silicon atom-containing compound;
a step of forming a resist film on the second underlayer film by using a resist composition;
a step of exposing the resist film; and
a step of developing the exposed resist film with a developer to form a resist pattern.

10. The resist pattern forming method according to claim 9,
wherein the exposure is a liquid immersion exposure.

11. The resist pattern forming method according to claim 9,
wherein the developer is a developer including an organic solvent.

12. The resist pattern forming method according to claim 9,
wherein the developer is an alkali developer.

13. A manufacturing method of an electronic device, comprising:
the resist pattern forming method according to claim 9.

14. The composition for forming an underlayer film according to claim 2, further comprising:
a crosslinking agent.

15. The composition for forming an underlayer film according to claim 2, further comprising:
an acid generator.

16. The composition for forming an underlayer film according to claim 15,
wherein the acid generator is a compound represented by any one of General Formula (1), (2), or (3), 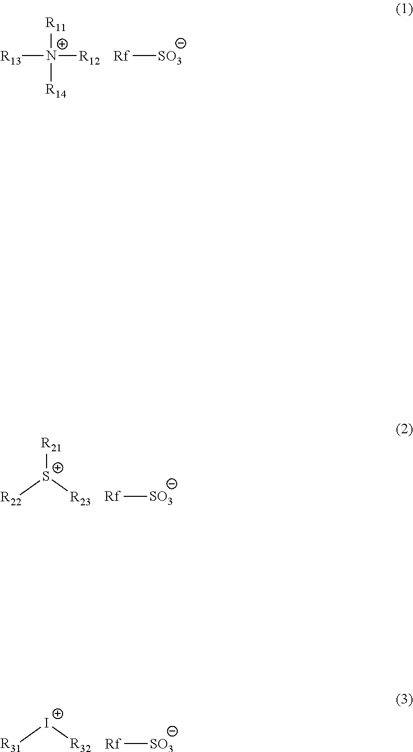
in General Formulae (1) to (3), R₁₁ to R₁₄, R₂₁ to R₂₃, R₃₁, and R₃₂ each independently represent a hydrogen atom, an alkyl group, or an aryl group, and Rf represents an organic group having one or more fluorine atoms,
in General Formula (2), two of R₂₁ to R₂₃ may be bonded to each other to form a ring.

17. The composition for forming an underlayer film according to claim 2,
wherein the halogen-based organic solvent includes one or more kinds selected from the group consisting of methylene chloride, chloroform, trichloroethylene, o-dichlorobenzene, and benzotrifluoride.

18. The composition for forming an underlayer film according to claim 2,
wherein the composition for forming an underlayer film includes the polymer containing an aromatic ring, and
the polymer containing an aromatic ring is a novolac resin having one or more repeating units represented by any of General Formula (A01), . . . , or (A06), 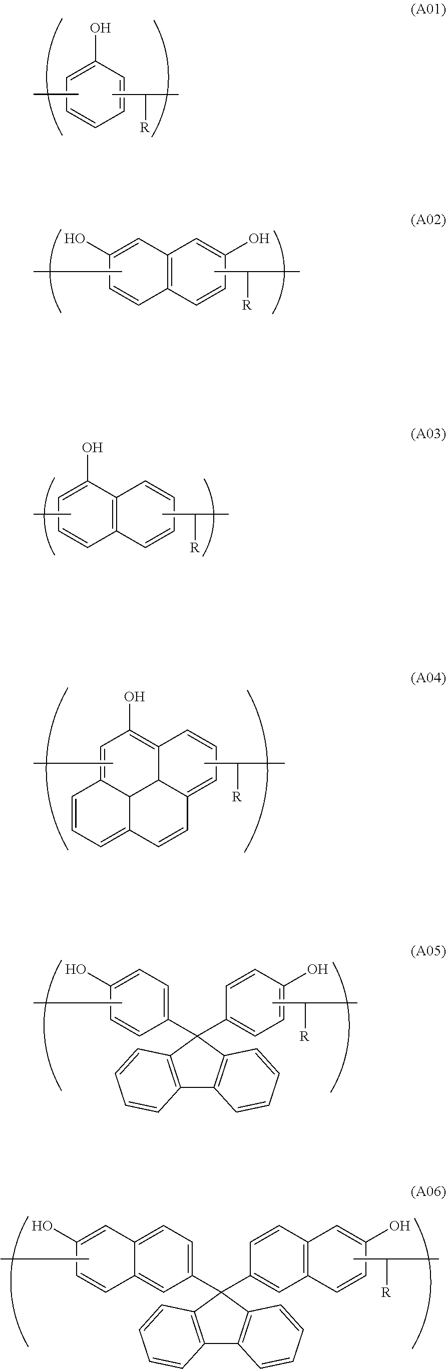
in General Formulae (A01) to (A06), R represents a hydrogen atom, an alkyl group, an alkenyl group, an alicyclic group, or an aryl group.

19. The composition for forming an underlayer film according to claim 18,
wherein the content of the halogen-based organic solvent is 0.1 to 10 ppm by mass with respect to a content of the novolac resin.

20. A resist pattern forming method comprising:
a step of forming an underlayer film on a substrate by using the composition for forming an underlayer film according to claim 2;
a step of forming a second underlayer film on the underlayer film by using a composition for forming a second underlayer film, which includes a silicon atom-containing compound;
a step of forming a resist film on the second underlayer film by using a resist composition;
a step of exposing the resist film; and
a step of developing the exposed resist film with a developer to form a resist pattern.
